(19) United States
(12) Patent Application Publication
(10) Pub. No.: US 2017/0103992 A1
(43) Pub. Date: Apr. 13, 2017

(54) SEMICONDUCTOR MEMORY DEVICE AND METHOD OF MANUFACTURING THE SAME

(71) Applicant: Kabushiki Kaisha Toshiba, Minato-ku (JP)

(72) Inventors: Ayaha HACHISUGA, Yokkaichi (JP); Daigo ICHINOSE, Nagoya (JP)

(73) Assignee: Kabushiki Kaisha Toshiba, Minato-ku (JP)

(21) Appl. No.: 15/046,674

(22) Filed: Feb. 18, 2016

Related U.S. Application Data
(60) Provisional application No. 62/238,357, filed on Oct. 7, 2015.

(51) Int. Cl. H01L 27/115

(52) U.S. Cl. CPC H01L 27/11556; H01L 27/11582

(57) ABSTRACT

An embodiment comprises: a memory cell array that includes a plurality of memory cells arranged in a stacking direction on a semiconductor substrate, and a plurality of first conductive layers arranged in the stacking direction on the semiconductor substrate and connected to the memory cells; a cover layer that covers at least some of side surfaces of each of the plurality of first conductive layers; and a second conductive layer commonly connected to ends of some of the plurality of first conductive layers. Moreover, the commonly connected ends of some of the plurality of first conductive layers and the second conductive layer are connected without being interposed by the cover layer.

### CROSS REFERENCE TO RELATED APPLICATION

This application is based upon and claims the benefit of priority from U.S. Provisional Patent Application No. 62/238,357, filed on Oct. 7, 2015, the entire contents of which are incorporated herein by reference.

### FIELD

Embodiments described herein relate to a semiconductor memory device and a method of manufacturing the same.

### BACKGROUND

A flash memory that stores data by accumulating a charge in a charge accumulation layer or floating gate, is known. Such a flash memory is connected by a variety of systems such as NAND type or NOR type, and configures a semiconductor memory device. In recent years, increasing of capacity and raising of integration level of such a semiconductor memory device have been proceeding. Moreover, a semiconductor memory device in which memory cells are disposed three-dimensionally (three-dimensional type semiconductor memory device) has been proposed to raise the integration level of the memory.

### BRIEF DESCRIPTION OF THE DRAWINGS

FIG. 1 is a plan view showing a schematic configuration of a semiconductor memory device according to a first embodiment.

FIG. 2 is an equivalent circuit diagram showing a configuration of a memory cell array 1 of the same semiconductor memory device.

FIG. 3 is a perspective view showing the configuration of the memory cell array 1 of the same semiconductor memory device.

FIG. 4 is a plan view showing the configuration of the same memory cell array 1.

FIGS. 5A and 5B are schematic perspective views showing examples of configuration of a stepped portion 12.

FIG. 6 is a schematic perspective cross-sectional view showing an example of configuration of one memory cell MC included in the same semiconductor memory device.

FIG. 7 is a plan view showing a configuration of part of the memory cell array 1 included in the same semiconductor memory device.

FIGS. 8A and 8B are schematic cross-sectional views showing the configuration of the same semiconductor memory device.

FIGS. 9 to 25 are schematic cross-sectional views showing a method of manufacturing the same semiconductor memory device.

FIG. 26 is a schematic cross-sectional view showing a configuration of a semiconductor memory device according to a second embodiment.

FIGS. 27 to 36 are schematic cross-sectional views showing a method of manufacturing the same semiconductor memory device.

FIG. 37 is a schematic cross-sectional view showing a configuration of a semiconductor memory device according to a first modified example.

FIG. 38 is a schematic cross-sectional view showing a method of manufacturing the same semiconductor memory device.

FIG. 39 is a schematic cross-sectional view showing a configuration of a semiconductor memory device according to a second modified example.

### DETAILED DESCRIPTION

A semiconductor memory device according to an embodiment comprises: a memory cell array that includes a plurality of memory cells arranged in a stacking direction on a semiconductor substrate, and a plurality of first conductive layers arranged in the stacking direction on the semiconductor substrate and connected to the memory cells; a cover layer that covers at least some of side surfaces of each of the plurality of first conductive layers; and a second conductive layer commonly connected to ends of some of the plurality of first conductive layers. Moreover, the commonly connected ends of some of the plurality of first conductive layers and the second conductive layer are connected without being interposed by the cover layer.

Next, semiconductor memory devices according to embodiments will be described in detail with reference to the drawings. Note that these embodiments are merely examples. For example, the semiconductor memory devices described below have a structure in which a memory string extends linearly in a perpendicular direction to a substrate, but a similar structure may be applied also to a U-shaped structure in which the memory string is doubled back on an opposite side midway. Moreover, each of the drawings of the semiconductor memory devices employed in the embodiments below is schematic, and thicknesses, widths, ratios, and so on, of layers are not necessarily identical to those of the actual semiconductor memory devices.

In addition, the embodiments described below relate to semiconductor memory devices having a structure in which a plurality of MONOS (Metal-Oxide-Nitride-Oxide-Semiconductor) type memory cells (transistors) are provided in a height direction, each of the MONOS type memory cells including: a semiconductor film acting as a channel provided in a column shape perpendicularly to a substrate; and a gate electrode film provided on a side surface of the semiconductor film via a charge accumulation layer. However, a similar structure may be applied also to a memory cell of another form, for example, a SONOS (Semiconductor-Oxide-Nitride-Oxide-Semiconductor) type memory cell or MANOS (Metal-Aluminum Oxide-Nitride-Oxide-Semiconductor) type memory cell, one employing hafnium oxide (HfOₓ) or tantalum oxide (TaOₓ) as an insulating layer, or a floating gate type memory cell.

### First Embodiment

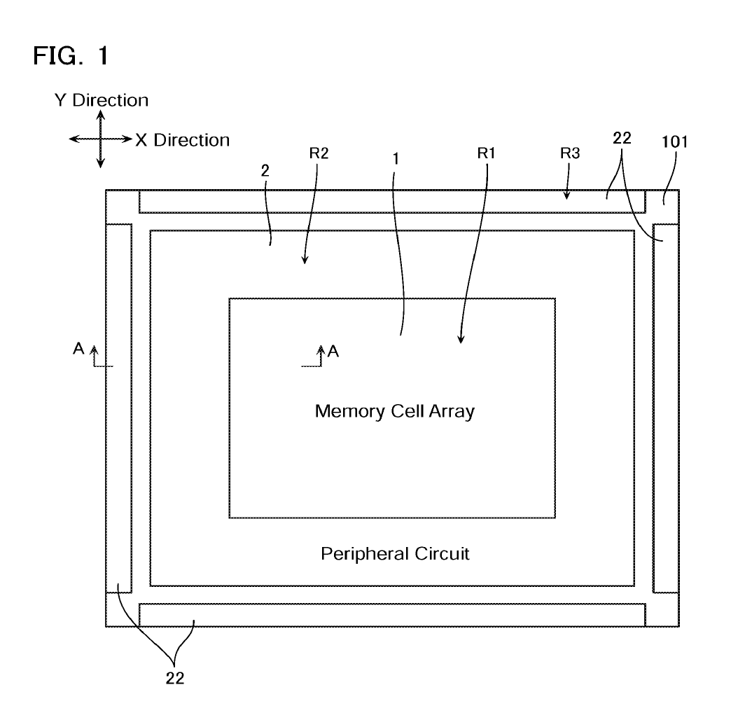

FIG. 1 is a plan view showing a schematic configuration of a semiconductor memory device according to a first embodiment. The semiconductor memory device according to the first embodiment comprises a memory cell array 1 provided on a substrate 101 used as a memory chip. A periphery of the memory cell array may be provided with a peripheral circuit 2 and a dummy stepped portion 22 that surrounds the peripheral circuit 2.

The memory cell array 1 comprises: a plurality of memory cells arranged three-dimensionally; and a stepped portion where wiring lines led out from the memory cells are formed in a stepped shape.

The peripheral circuit 2 is connected to the memory cell array 1 via a plurality of bit lines and a plurality of word lines. The peripheral circuit 2 is formed of a CMOS circuit provided on the substrate 101, and functions as a decoder, a sense amplifier, a state machine, a voltage generating circuit, and so on.

Note that in the description below, a region on the substrate 101 provided with the memory cell array 1 will be called a memory cell array region R1, a region on the substrate 101 provided with the stepped wiring lines led out from the memory cells will be called a contact region CR, a region on the substrate 101 provided with the peripheral circuit 2 will be called a peripheral circuit region R2 (transistor region), and a region on the substrate 101 provided with the dummy stepped portion 22 will be called a dummy region R3.

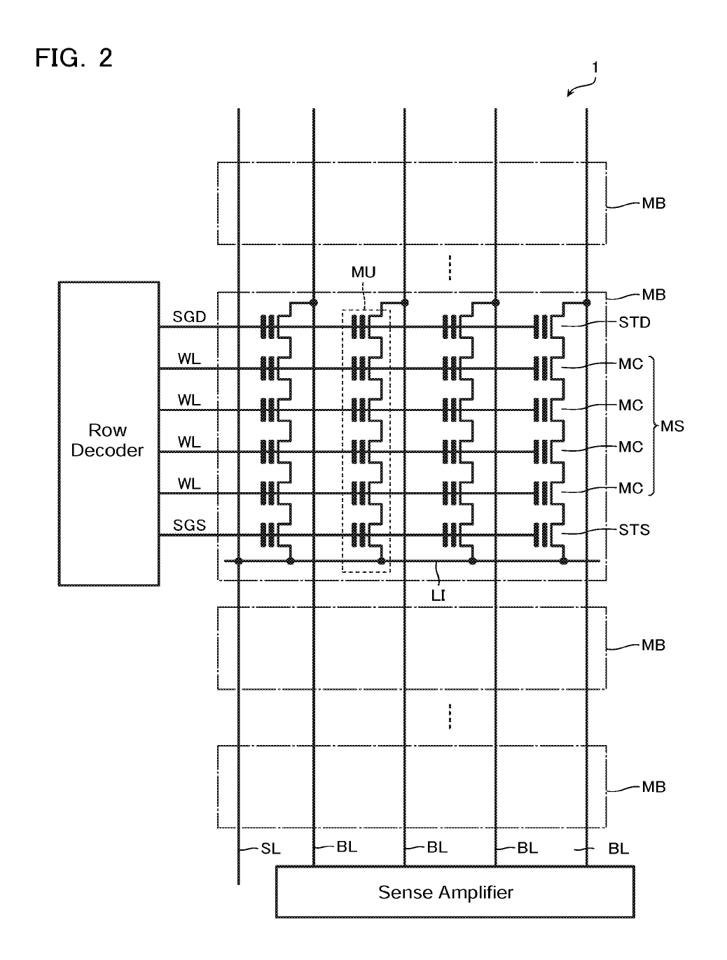

Next, a circuit configuration of part of the memory cell array 1 according to the present embodiment will be described with reference to FIG. 2. FIG. 2 is an equivalent circuit diagram showing a configuration of part of the memory cell array 1 according to the present embodiment.

As shown in FIG. 2, the memory cell array 1 according to the present embodiment comprises a plurality of memory blocks MB. Moreover, a plurality of bit lines BL and a source line SL are commonly connected to these plurality of memory blocks MB. Each of the memory blocks MB is connected to the sense amplifier via the bit lines BL, and is connected to an unillustrated source line driver via the source line SL.

The memory block MB comprises a plurality of memory units MU that have their one ends connected to the bit lines BL and have their other ends connected to the source line SL via a source contact LI.

As shown in FIG. 2, the memory unit MU comprises a plurality of memory cells MC connected in series. As will be mentioned later, the memory cell MC comprises a semiconductor layer, a charge accumulation layer, and a control gate, and accumulates a charge in the charge accumulation layer based on a voltage applied to the control gate, thereby changing a threshold value of the memory cell MC. Note that hereafter, the plurality of memory cells MC connected in series will be called a “memory string MS”.

As shown in FIG. 2, the word lines WL are commonly connected to the control gates of pluralities of the memory cells MC configuring different memory strings MS, respectively. These pluralities of memory cells MC are connected to a row decoder via the word lines WL.

As shown in FIG. 2, the memory unit MU comprises a drain side select gate transistor STD connected between the memory string MS and the bit line BL. Drain side select gate line SGD is connected to a control gate of the drain side select gate transistor STD. The drain side select gate line SGD is connected to the row decoder, and selectively connects the memory string MS and the bit line BL based on an inputted signal.

As shown in FIG. 2, the memory unit MU comprises a source side select gate transistor STS connected between the memory string MS and the source contact LI. Source side select gate line SGS is connected to a control gate of the source side select gate transistor STS. The source side select gate line SGS is connected to the row decoder, and selectively connects the memory string MS and the source line SL based on an inputted signal.

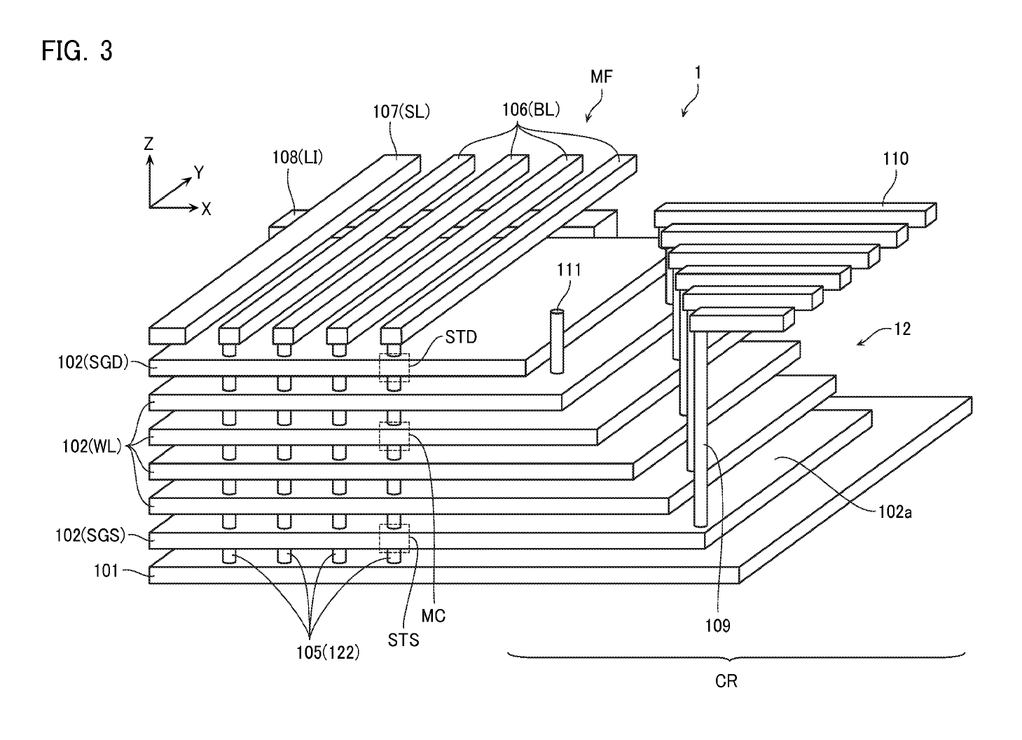

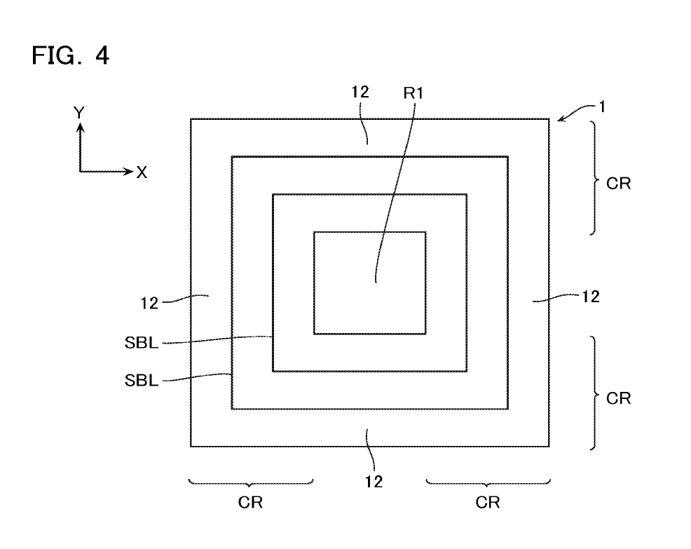

Next, a schematic configuration of the memory cell array 1 according to the present embodiment will be described with reference to FIGS. 3 and 4. FIG. 3 is a schematic perspective view showing a configuration of part of a memory finger MF (memory cell group). FIG. 4 is a schematic plan view showing a configuration of a stepped portion 12 of the memory cell array 1. Note that in FIGS. 3 and 4, part of the configuration is omitted.

As shown in FIG. 3, the memory finger MF according to the present embodiment comprises: the substrate 101; and a plurality of conductive layers 102 stacked in a Z direction on the substrate 101. In addition, the memory finger MF includes a plurality of memory columnar bodies 105 extending in the Z direction. As shown in FIG. 3, an intersection of the conductive layer 102 and the memory columnar body 105 functions as the source side select gate transistor STS, the memory cell MC, or the drain side select gate transistor STD. The conductive layer 102 is formed of a conductive layer of tungsten (W) or polysilicon, for example, and functions as the word line WL, the source side select gate line SGS, and the drain side select gate line SGD.

As shown in FIG. 3, the plurality of conductive layers 102 are formed in a stepped shape and configure the stepped portion 12, at their ends in an X direction in the contact region CR.

The stepped portion 12 comprises a support 111 (HR) extending in the Z direction to penetrate the stepped portion 12.

Moreover, disposed in the stepped portion 12 is a contact 109 for electrically connecting an upper wiring line 10 and each of layers configuring the stepped portion 12. As shown in FIG. 3, the memory finger MF comprises a conductive layer 108 that faces side surfaces in a Y direction of the plurality of conductive layers 102, and extends in the X direction. A lower surface of the conductive layer 108 contacts the substrate 101. The conductive layer 108 is formed of a conductive layer of tungsten (W), for example, and functions as the source contact LI.

In addition, as shown in FIG. 3, disposed upwardly of the memory finger MF are a conductive layer 106 and a conductive layer 107. The conductive layer 106 functions as the bit line BL, and the conductive layer 107 functions as the source line SL.

FIG. 4 is a schematic plan view showing the configuration of the stepped portion 12 of the memory cell array 1. In FIG. 3 described above, a plurality of the conductive layers 102 of the memory cell array 1 configure the stepped portion 12 at their ends in the X direction. However, as shown in FIG. 4, the conductive layers 102 of the memory cell array 1 are formed in a stepped shape and configure the stepped portion 12 also at their ends in the Y direction. That is, the semiconductor memory device according to the present embodiment includes the contact region CR comprising the stepped portion 12 in a periphery in each of the X and Y directions, of the memory cell array region R1.

FIG. 4 shows a step boundary SBL where a level difference of the stepped portion 12 of the contact region CR changes. In other words, in FIG. 4, a region surrounded by the SBL has an identical height, and that height decreases with increasing distance from the memory cell array region R1 (with increasing distance from a substrate center).

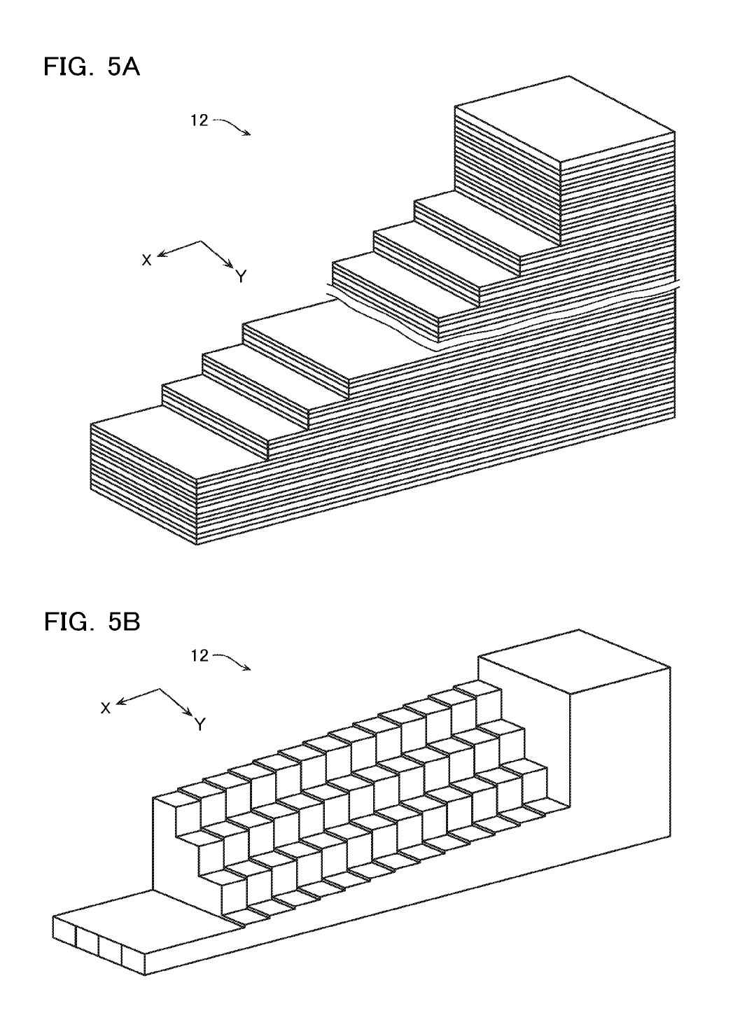

Note that the conductive layers 102 configuring the word lines WL may have a stepped structure expanding one-dimensionally only in the X direction as shown in FIG. 5A, or may have a two-dimensional stepped structure expanding in both of the X direction and the Y direction as shown in FIG. 5B.

Moreover, as will be mentioned later, the dummy region R3 is also provided with the stepped portion 22 having a stepped structure. This stepped portion 22 may also adopt the stepped structures of the kinds shown in FIGS. 5A and 5B.

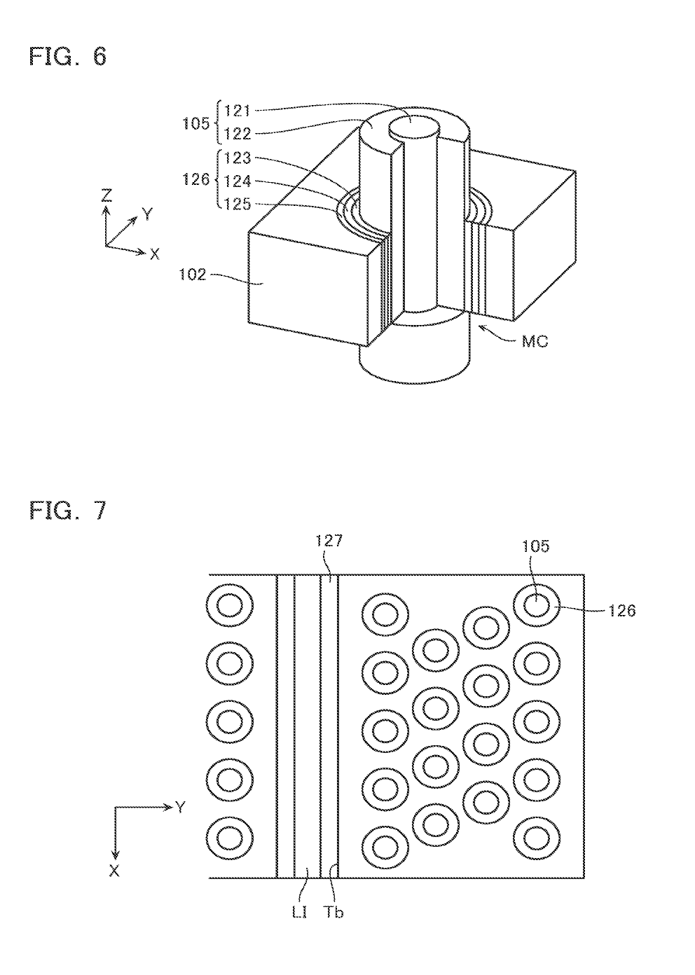

Next, a schematic configuration of the memory cell MC according to the present embodiment will be described with reference to FIG. 6. FIG. 6 is a schematic perspective view showing the configuration of the memory cell MC. Note that FIG. 6 shows the configuration of the memory cell MC, but the source side select gate transistor STS and the drain side select gate transistor STD may also be configured similarly to the memory cell MC. Moreover, in FIG. 6, part of the configuration is omitted.

As shown in FIG. 6, the memory cell MC is provided at an intersection of the conductive layer 102 and the memory columnar body 105. The memory columnar body 105 comprises: a core insulating layer 121; and a semiconductor layer 122 that covers a sidewall of the core insulating layer 121. Furthermore, a memory film 126 is provided between the semiconductor layer 122 and the conductive layer 102. The memory film 126 includes a tunnel insulating layer 123, a charge accumulation layer 124, and a block insulating layer 125.

The core insulating layer 121 is formed of an insulating layer of silicon oxide, for example. The semiconductor layer 122 is formed of a semiconductor layer of polysilicon, for example. Moreover, the semiconductor layer 122 functions as a channel of the memory cell MC, the source side select gate transistor STS, and the drain side select gate transistor STD. The tunnel insulating layer 123 is formed of an insulating layer of silicon oxide, for example. The charge accumulation layer 124 is formed of an insulating layer capable of accumulating a charge, of silicon nitride, for example. The block insulating layer 125 is formed of an insulating layer of silicon oxide, for example.

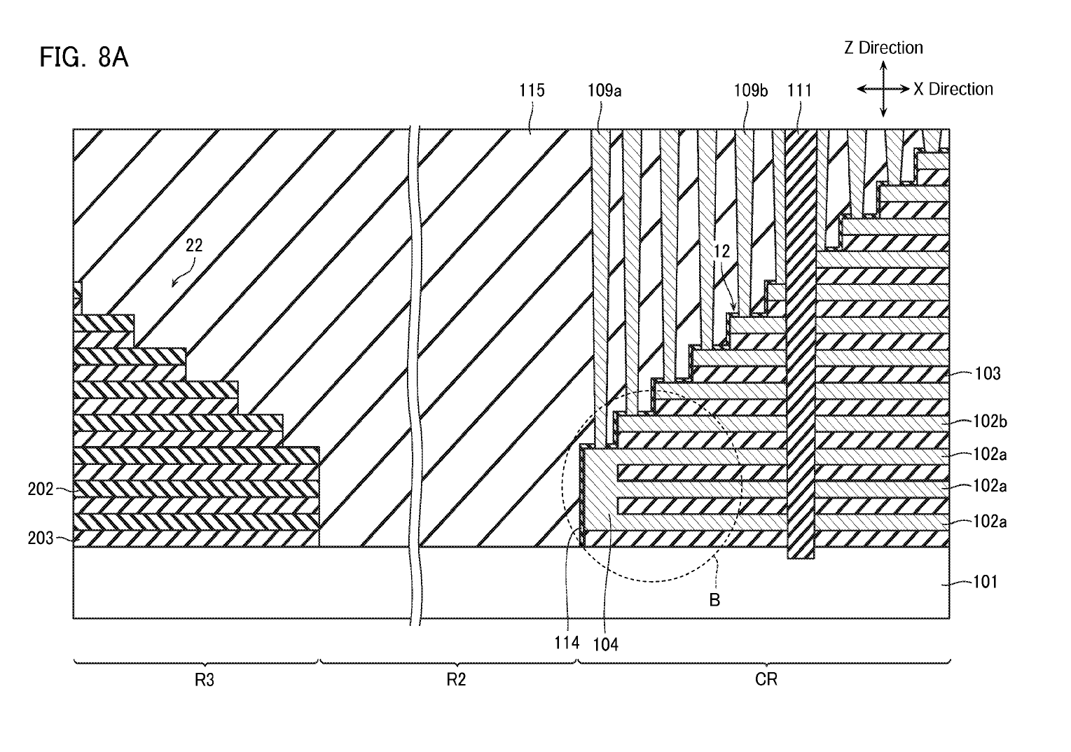

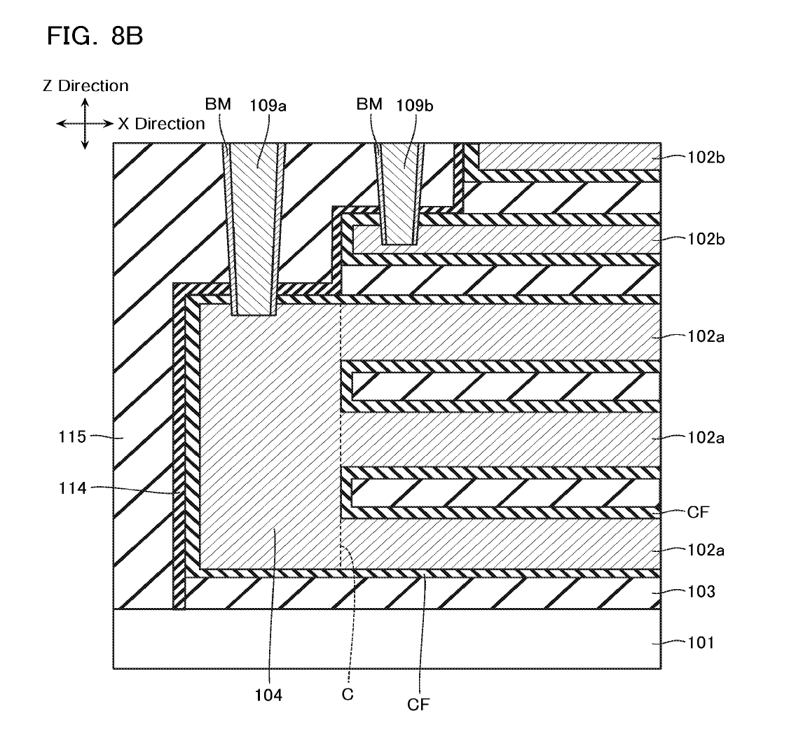

Next, a configuration of the semiconductor memory device according to the present embodiment will be described in more detail with reference to FIGS. 7, 8A, and 8B. FIG. 7 is a plan view showing a configuration of part of the memory cell array 1; and FIG. 8A is a schematic cross-sectional view showing the configuration of the semiconductor memory device according to the present embodiment, and shows a cross-section taken along the line AA of FIG. 1. Note that in FIG. 8A, illustration of the peripheral circuit 2 is omitted. FIG. 8B is an enlarged cross-sectional view of the portion B of FIG. 8A.

As shown in FIG. 7, the memory columnar bodies 105 are arranged so as to be lined up in an oblique direction to the X direction (word line direction) and the Y direction (bit line direction), whereby an array density of the memory columnar bodies 105 is increased, and an array density of the memory cells MC is raised. However, this is merely an example, and it is also possible to configure such that the memory columnar bodies 105 are aligned along the X direction and the Y direction. In addition, the source contact LI is formed in a striped shape having the X direction as its longitudinal direction.

The source contact LI is implanted, via an inter-layer insulating film 127, in a trench Tb that divides the memory cell array 1 in block units. A lower end of the source contact LI contacts a diffusion layer formed in a surface of the substrate 101, and an upper end of the source contact LI is connected to the source line SL via an upper layer wiring line.

FIG. 8A is a schematic cross-sectional view in the Z-X directions showing a configuration of the above-mentioned stepped portion 12 of the memory cell array 1. Note that in FIG. 8A, part of the configuration is omitted. Moreover, the configuration shown in FIG. 8A is merely an example, and a detailed configuration, and so on, may be appropriately changed.

As shown in FIG. 8A, in the stepped portion 12 of the contact region CR, a plurality of conductive layers 102a and 102b are stacked on the substrate 101 via an insulating layer 103. Of these conductive layers 102a and 102b, the plurality of layers (in the present embodiment, three layers) of conductive layers 102a from a lowermost layer function as the source side select gate line SGS connected to the source side select gate transistor STS. The conductive layer 102b more upward than the conductive layer 102a functions as the word line WL. The word line WL may include a dummy word line. Moreover, although not illustrated in FIG. 8A, a plurality of layers of conductive layers from an uppermost layer, of the stacked conductive layers 102 function as the drain side select gate line SGD connected to the drain side select gate transistor STD.

The insulating layer 103 is formed of silicon oxide, for example. The conductive layers 102a and 102b are formed of a metal such as tungsten or from polysilicon, as mentioned above. Moreover, although illustration thereof is omitted in FIG. 8A, a cover film CF is provided in a periphery of the conductive layers 102a and 102b, so as to cover at least some of side surfaces of the conductive layers 102a and 102b. The cover film CF includes a block insulating layer, a high permittivity film, and a barrier metal film.

As shown in FIG. 8A, the conductive layer 102b is formed in a stepped shape in the stepped portion 12. That is, an end in the X direction of the conductive layer 102b recedes in a direction of increasing distance from the peripheral circuit region R2 and the dummy region R3 with increasing distance in the Z direction from the substrate 101. In other words, the conductive layer 102b has a height that increases with increasing distance from the peripheral circuit region R2 and the dummy region R3.

The stepped portion 12 is provided with the support 111 for maintaining a posture of the stepped structure during a later-mentioned insulating layer replacing step. A block layer 114 is provided on a surface of the stepped portion 12. Moreover, an inter-layer insulating layer 115 is disposed so as to cover the stepped portion 12.

The block layer 114 is formed of silicon nitride, for example. The inter-layer insulating layer 115 is formed of silicon oxide, for example.

In the present embodiment, only the contact region CR including the stepped portion 12, of the memory cell array region R1, is illustrated, but provided on the inside of the contact region CR (in a direction of increasing distance from the end of the stepped portion 12) is the memory cell array region R1 where the memory columnar body 105, and so on, are disposed.

Moreover, as shown in FIG. 8A, in the present embodiment, ends of some of the conductive layers 102 (in the present embodiment, the three stacked layers of conductive layers 102a from the lowermost layer) are provided with a conductive layer 104 commonly connected to the ends of these three layers of conductive layers 102a.

FIG. 8B shows an enlarged cross-sectional view of a portion including these three layers of conductive layers 102a and the conductive layer 104.

As shown in FIG. 8B, the conductive layers 102a and 102b are provided with the cover film CF such that at least some of their side surfaces are covered. The conductive layer 104 is disposed at ends of the conductive layers 102a so as to extend in the Z direction to straddle the three layers of conductive layers 102a. As a result, the three layers of conductive layers 102a are electrically connected via the conductive layer 104. Moreover, the three layers of conductive layers 102a from the lowermost layer and the conductive layer 104 are connected without being interposed by the cover film CF, at their boundary C. Note that hereafter, illustration of the cover film CF will sometimes be omitted.

The conductive layer 104 connected to the ends of the conductive layers 102a has a contact 109a connected thereto. In other words, the conductive layers 102a functioning as the source side select gate line SGS are electrically connected to an upper wiring line via the conductive layer 104.

A contact 109b is connected to close to an end of each of the conductive layers 102b in higher layers than the three layers of conductive layers 102a from the lowermost layer. The conductive layer 102b functioning as the word line WL and an upper wiring line, and so on, are electrically connected by the contact 109b. The contacts 109a and 109b have their periphery covered by a barrier metal BM.

Thus, in the present embodiment, there is only one contact 109a connected to the source side select gate line SGS formed of the plurality of conductive layers 102a, and this is less than the number of conductive layers 102a configuring the source side select gate line SGS. This makes it unnecessary for a contact to be provided to each of the plurality of conductive layers 102a, hence enables area of the contact region CR to be reduced. That is, ends in the X direction (direction of increasing distance from the memory cell array region R1 and increasing closeness to the peripheral circuit region R2 and dummy region R3) of the plurality of conductive layers 102a configuring the source side select gate line SGS are aligned and commonly connected by the conductive layer 104 at those ends. Moreover, the contact 109a is connected to this conductive layer 104. Therefore, it becomes unnecessary to configure the plurality of conductive layers 102a as a stepped structure in order to connect a contact to each of the plurality of conductive layers 102a, and area of the contact region CR can be reduced proportionately.

Note that in the present embodiment, the boundary where the conductive layer 102a and the conductive layer 104 are connected substantially matches an end in the X direction of the conductive layer 102b in a fourth layer from the lowermost layer, but a position of the above-described boundary is not limited to this.

In addition, as shown in FIG. 8A, the dummy stepped portion 22 is provided also in the dummy region R3. The dummy stepped portion 22 has a configuration of a plurality of insulating layers 202 and insulating layers 203 stacked alternately on the substrate 101. Moreover, a portion facing the conductive layers 102a, of the dummy stepped portion 22, that is, the six layers of insulating layers 202 and insulating layers 203 counting from a substrate 101 side, do not have a stepped structure, and have their lengths in the X direction aligned. Moreover, a portion facing the conductive layers 102b of the dummy stepped portion 22, that is, the insulating layers 202 and insulating layers 203 in seventh and higher layers counting from the substrate 101 side, have a stepped structure.

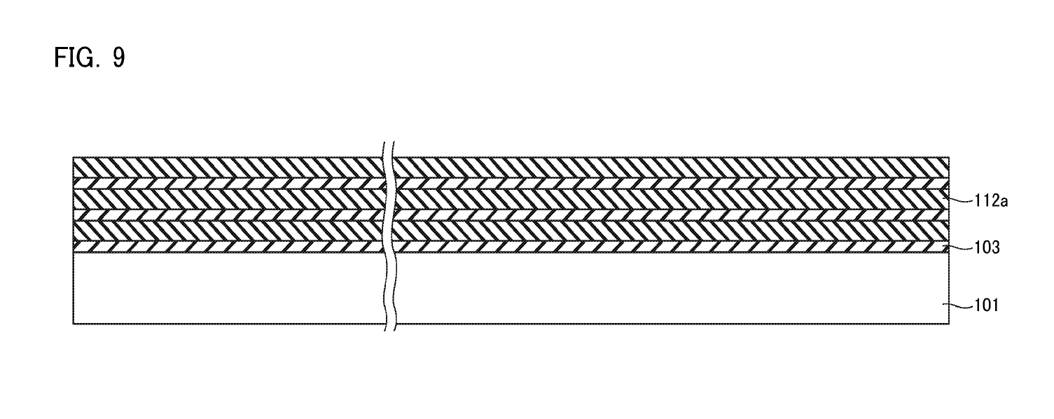

Next, a method of manufacturing the semiconductor memory device according to the present embodiment will be described with reference to FIGS. 9 to 25. FIGS. 9 to 25 are schematic cross-sectional views for explaining the same method of manufacturing.

As shown in FIG. 9, a plurality of the insulating layers 103 and sacrifice layers 112a are stacked alternately on the substrate 101. The insulating layer 103 is formed of silicon oxide, for example. The sacrifice layer 112a is formed of silicon nitride, for example. This sacrifice layer 112a will be replaced later by a conductive film to become the conductive layer 102a.

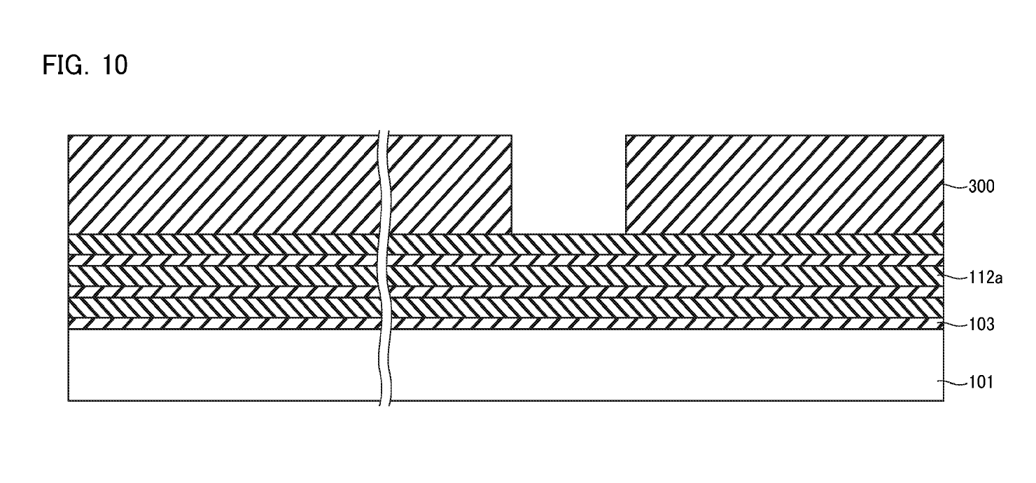

As shown in FIG. 10, a resist 300 is disposed. This resist 300 is disposed opening a region where, as will be described later, a sacrifice layer 112c which will later become the conductive layer 104 is disposed.

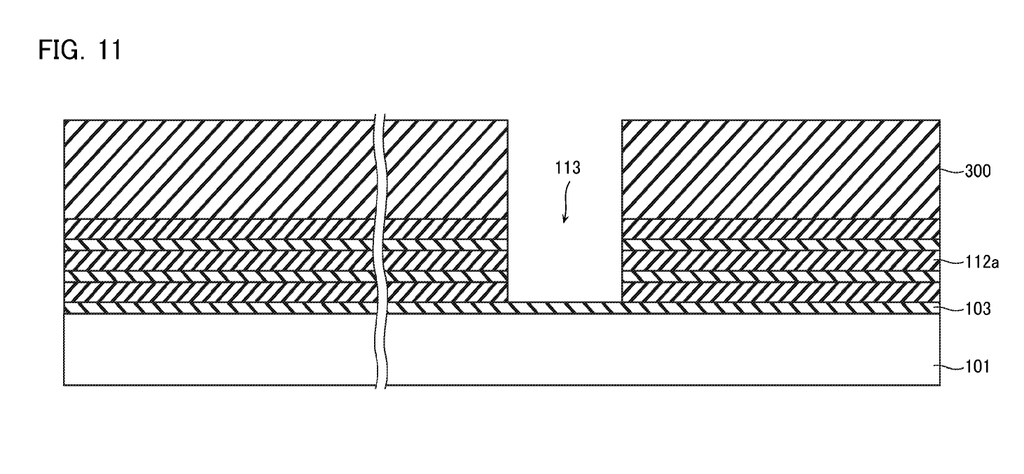

As shown in FIG. 11, the insulating layers 103 and sacrifice layers 112a disposed in an opening portion of the resist 300 are removed, using the resist 300 as a mask. Thus, a gap 113 penetrating some of the insulating layers 103 and at least two layers of the sacrifice layers 112a, is formed.

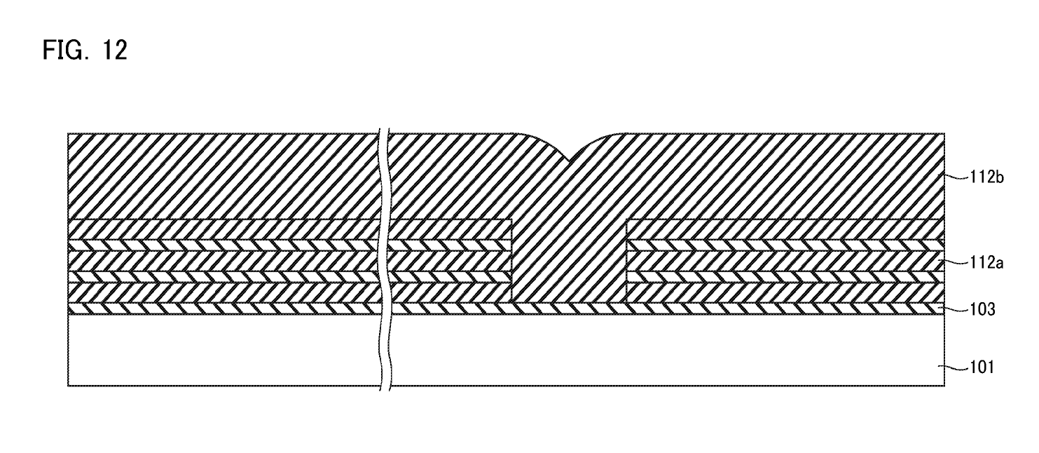

As shown in FIG. 12, a sacrifice layer 112b is disposed so as to fill the gap 113. This sacrifice layer 112b may be formed of the same material as the sacrifice layer 112a. Specifically, the sacrifice layer 112b may be formed of silicon nitride, for example.

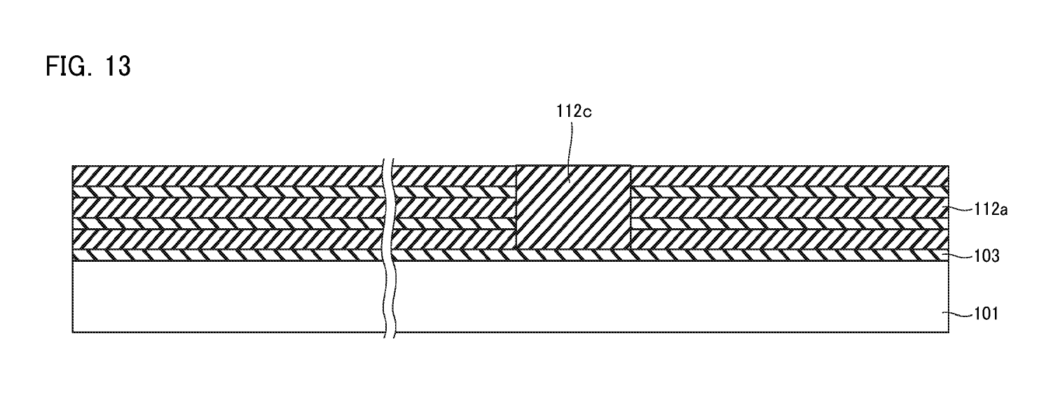

As shown in FIG. 13, part of the sacrifice layer 112b is removed by etching employing RIE or by CMP, and so on, and a sacrifice layer 112c is obtained. At this time, conditions of the etching or CMP, and so on, are adjusted such that an upper surface of the sacrifice layer 112c and an uppermost surface of the stacked insulating layers 103 and sacrifice layers 112a substantially match.

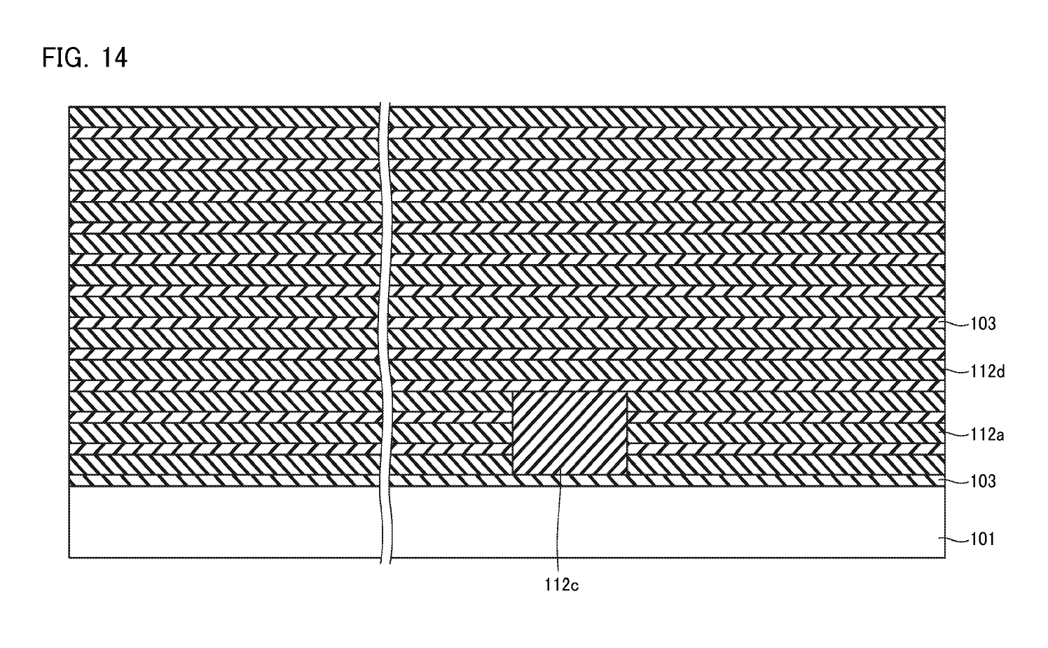

As shown in FIG. 14, a plurality of the insulating layers 103 and sacrifice layers 112d are stacked alternately on upper surfaces of the sacrifice layer 112c and the uppermost layer sacrifice layer 112a formed in the step described by FIG. 13. The sacrifice layer 112d is formed of an identical material to the sacrifice layers 112a and 112c. The sacrifice layer 112d will be replaced by a conductive film in a later step to become the conductive layer 102b.

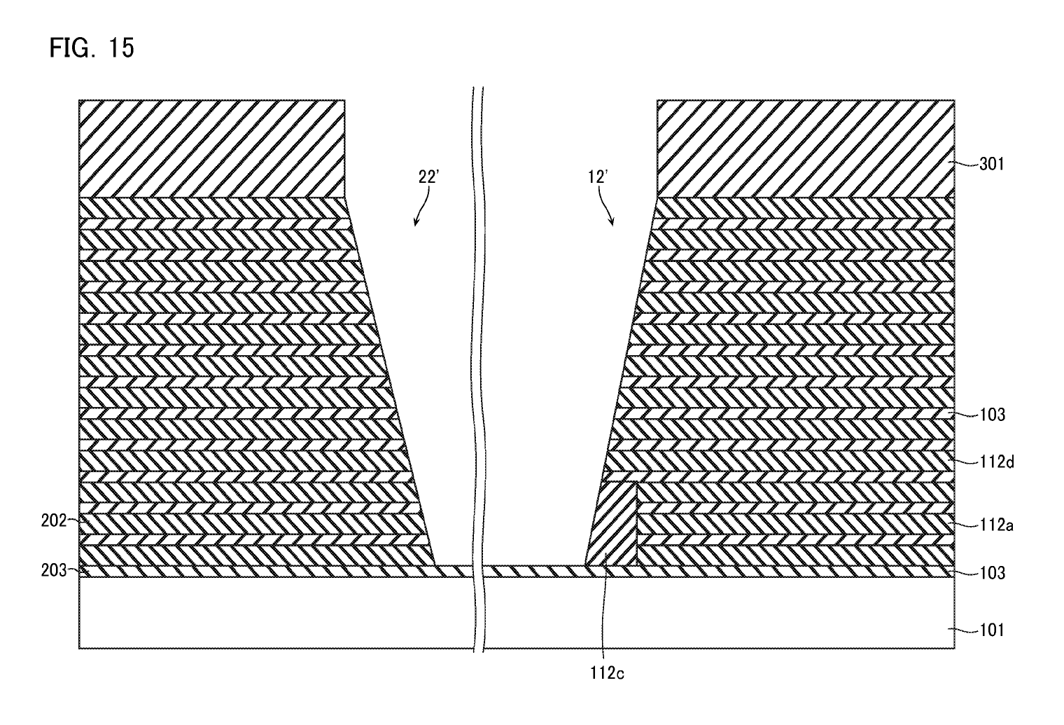

As shown in FIG. 15, the stacked insulating layers 103, sacrifice layers 112a, and sacrifice layers 112d are divided into a portion 12′ which will later become the stepped portion 12 and a portion 22′ which will later become the dummy stepped portion 22, by etching using a resist 301 as a mask. In addition, part of the sacrifice layer 112c is removed.

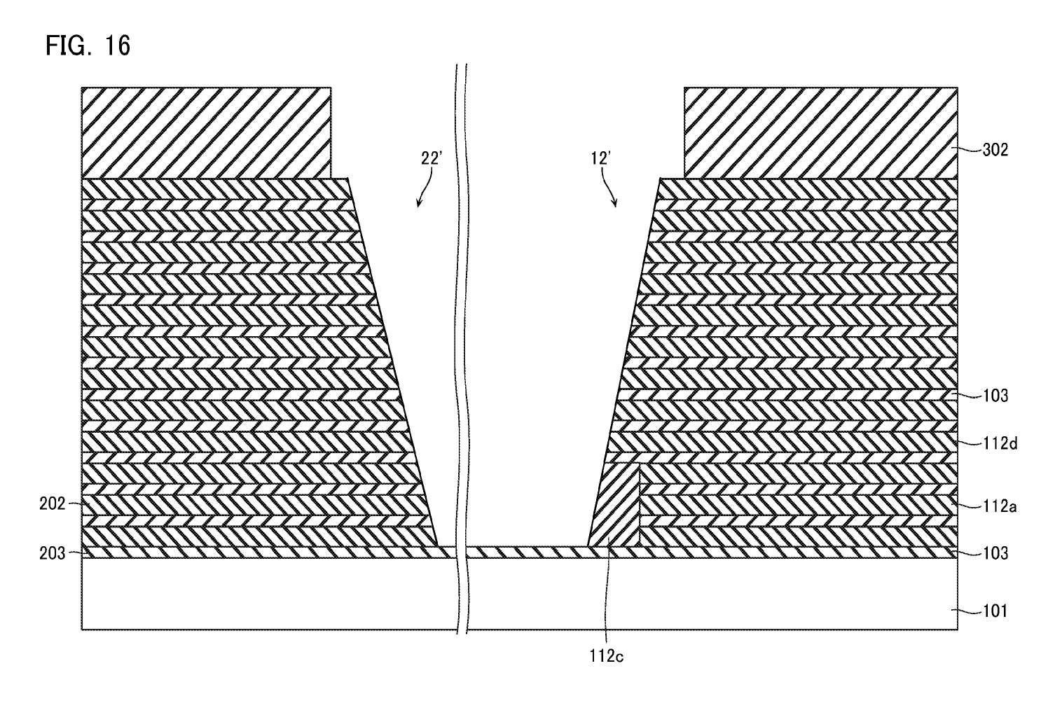

As shown in FIG. 16, a resist 302 is disposed. A position of this resist 302 will be a reference of a position of a leading edge of the stepped structure when the stepped portion 12 is formed, as will be mentioned later. That is, a leading edge of this resist 302 will be a position of a leading edge of a stepped structure portion of the stepped portion 12 that is formed.

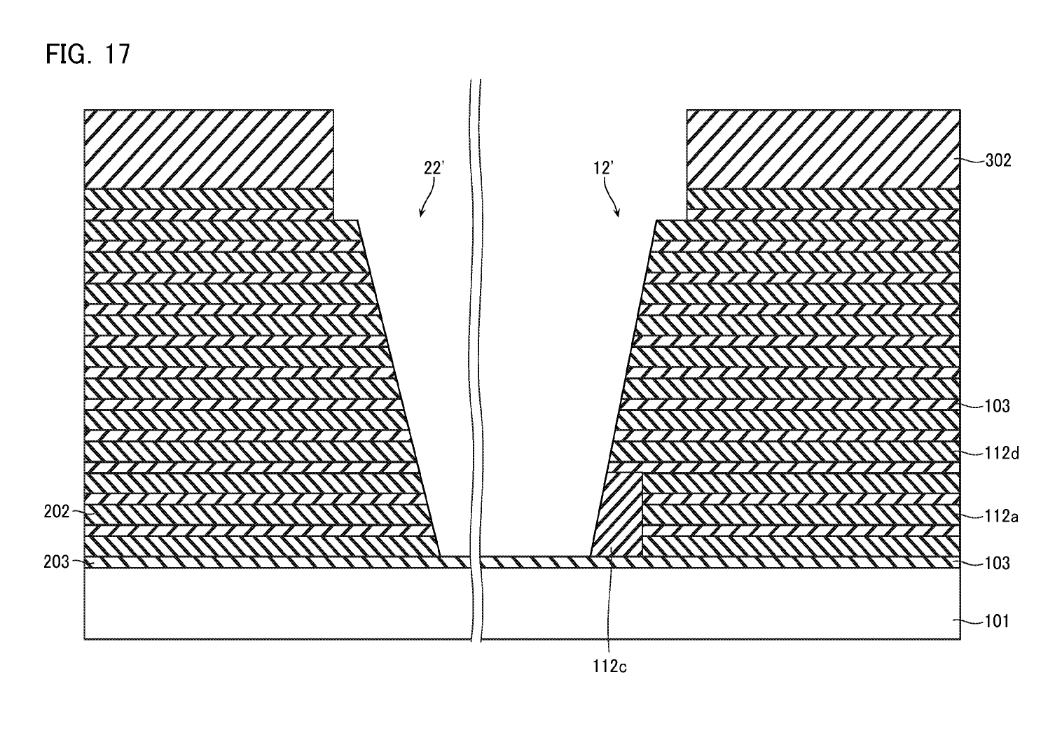

As shown in FIG. 17, one layer each of the insulating layers 103 and sacrifice layers 112d are etched using the resist 302 as a mask, whereby a first stage level difference is formed.

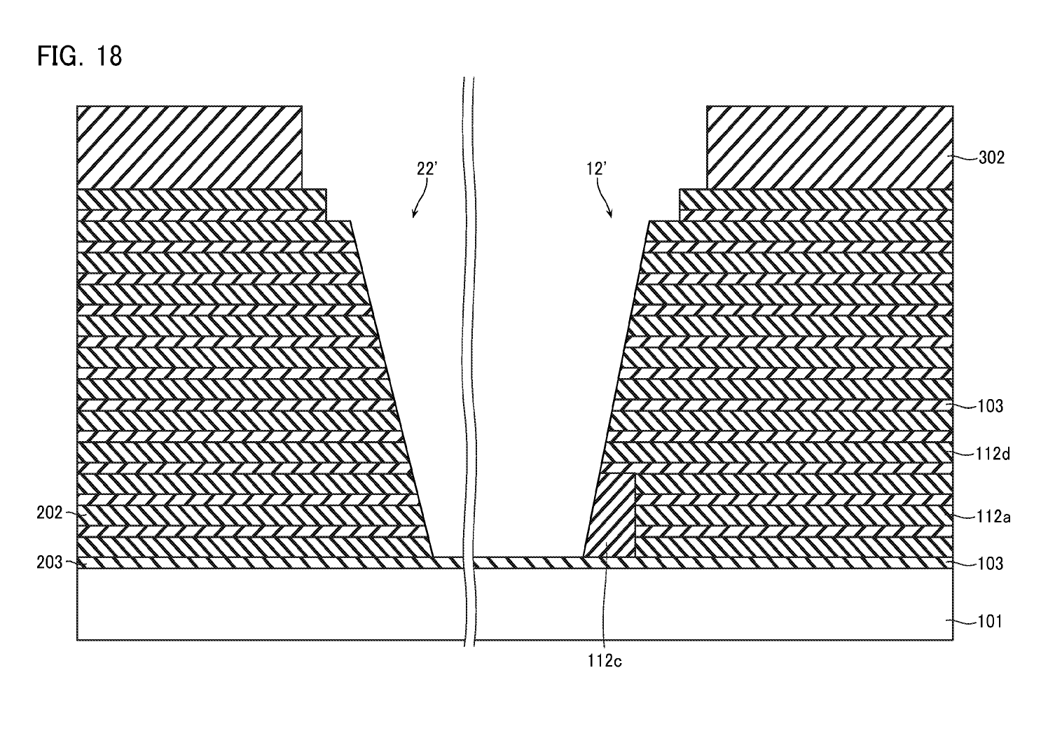

As shown in FIG. 18, the resist 302 is slimmed to the extent of a width in the X direction of the level difference of the stepped portion 12.

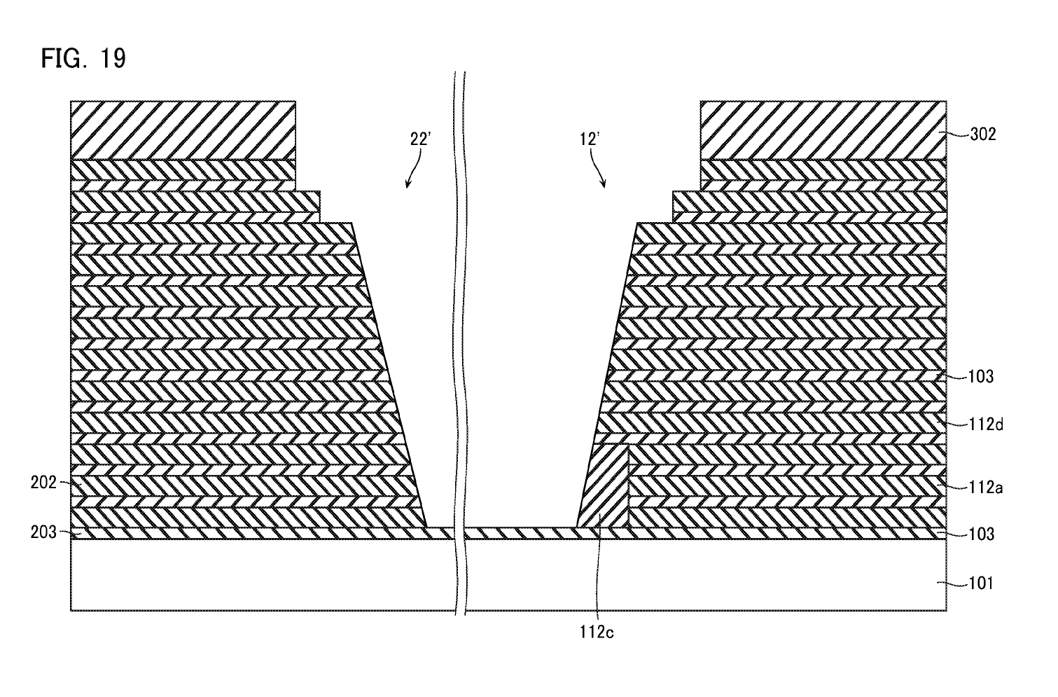

As shown in FIG. 19, one layer each of the insulating layers 103 and sacrifice layers 112d are again etched, whereby a second stage level difference is formed.

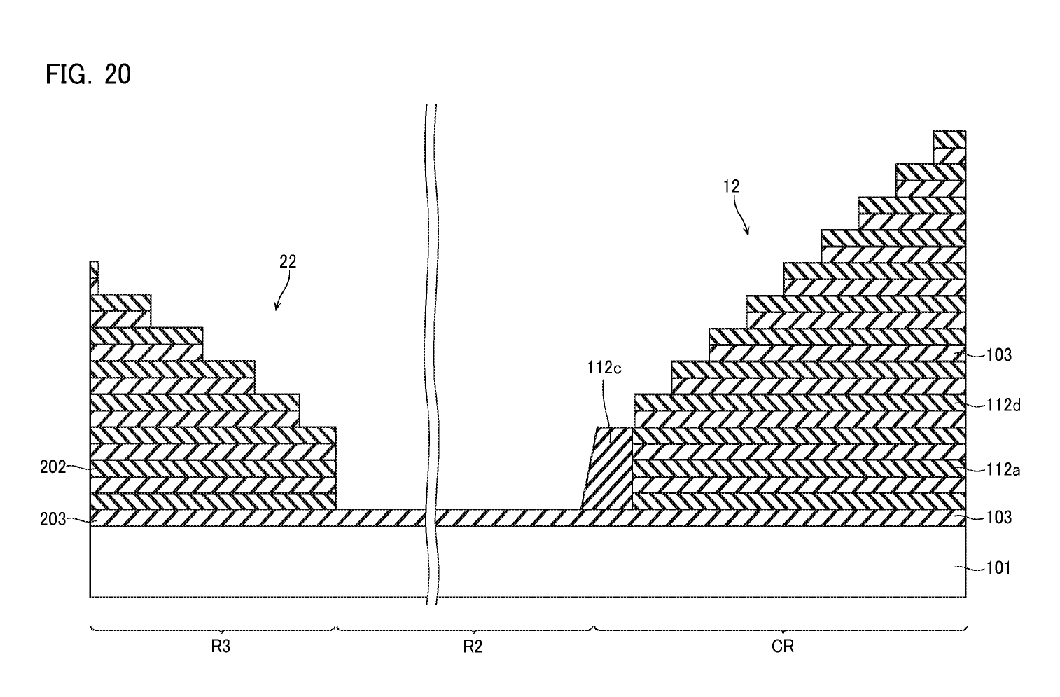

Slimming of the resist 302 and etching of the insulating layer 103 and sacrifice layer 112d are repeated a desired number of times, and the configuration shown in FIG. 20 is obtained. Thus, the stepped portion 12 is formed in the contact region CR. Moreover, in the dummy region R3, the dummy stepped portion 22 having a similar configuration to the stepped portion 12, is formed.

In the present embodiment, the etching for forming the above-described stepped structure is performed to the fourth layer insulating layer 103 counting from the substrate 101 and the lowermost layer sacrifice layer 112d. Therefore, the sacrifice layers 112d which will later become the conductive layers 102b are all etched, whereby the stepped structure is formed. The sacrifice layers 112a which will later become the conductive layers 102a are not etched and do not undergo formation of the stepped structure.

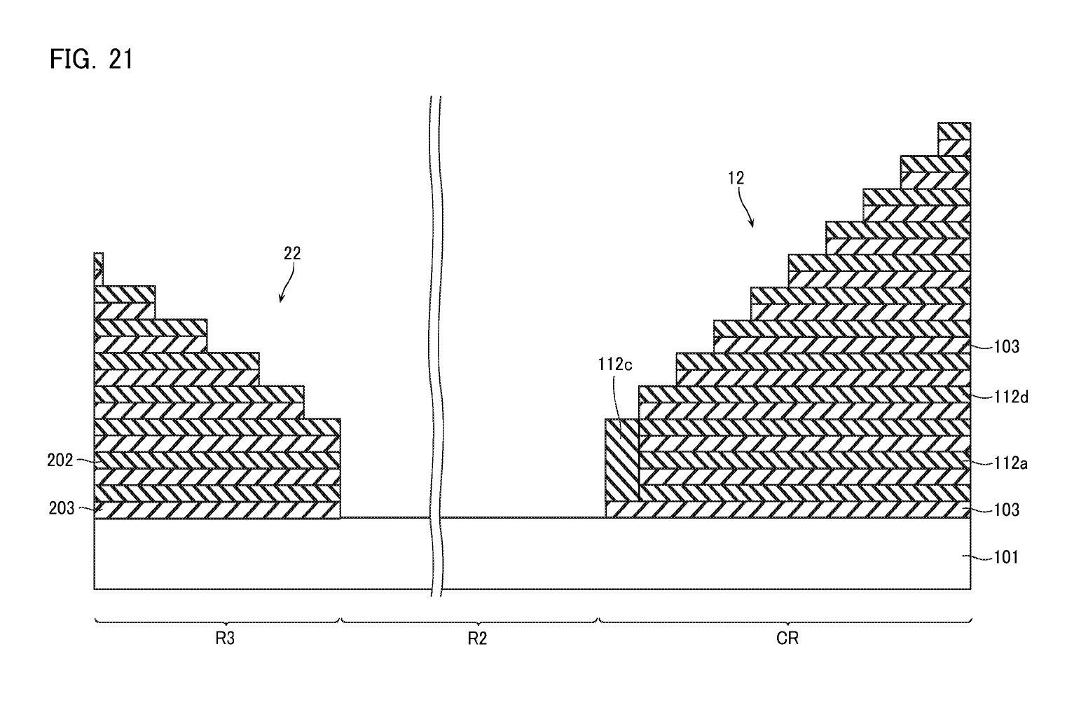

As shown in FIG. 21, part of the sacrifice layer 112c and part of the lowermost layer insulating layer 103 are removed by etching. Note that this step may be omitted.

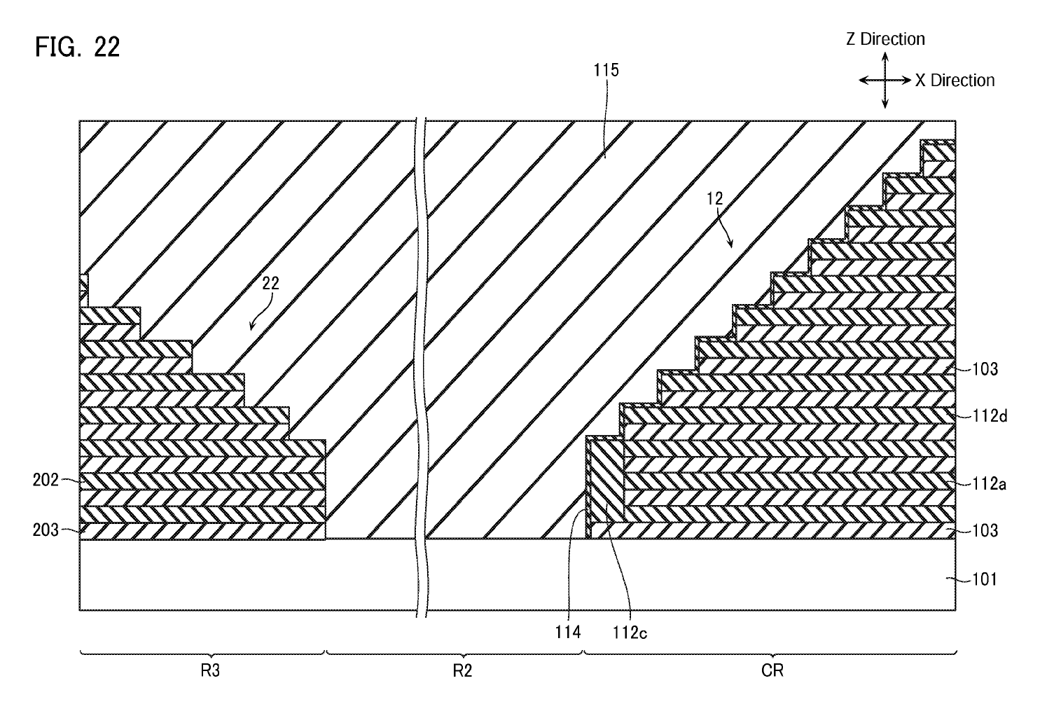

As shown in FIG. 22, the block layer 114 is formed on a surface of the formed stepped portion 12. The inter-layer insulating layer 115 is deposited on an entire surface of the unillustrated memory cell array region R1, the contact region CR, the peripheral circuit region R2, and the dummy region R3, so as to cover the block layer 114.

This block layer 114 functions as an etching stopper when forming a contact of each stage of the stepped structure. However, in the present embodiment, as shown in FIG. 22, the sacrifice layer 112c is disposed extending in the Z direction so as to commonly contact the ends of each of the plurality of sacrifice layers 112a. In this case, in a step of removing the sacrifice layer 112a and the sacrifice layer 112c to be replaced by the conductive film, a gap of a portion where the sacrifice layer 112c was disposed becomes large. Thereupon, a load applied to the block layer 114 of that portion, that is, a portion disposed on an upper surface and side surface of the sacrifice layer 112c becomes larger than a load applied to the block layer 114 of another portion, and there is a risk that the stepped structure ends up collapsing. In such a case, it is also possible for all of the block layer 114 or the portion contacting the upper surface and side surface of the sacrifice layer 112c, of the block layer 114, to be thickened.

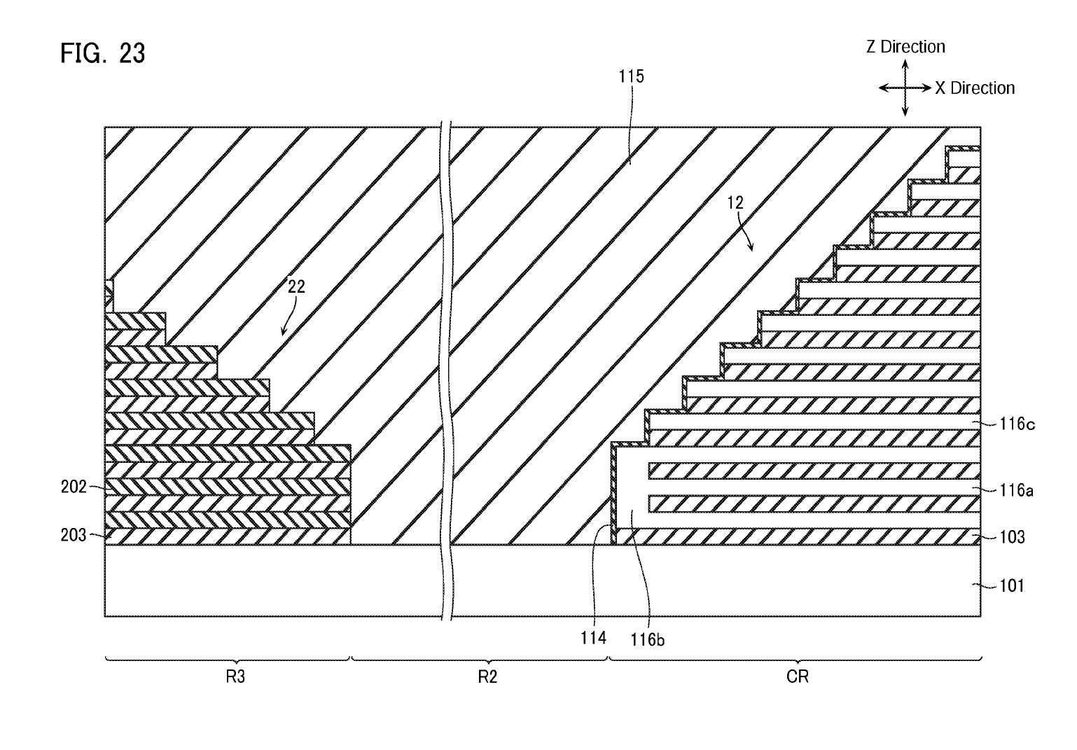

As shown in FIG. 23, the sacrifice layers 112a, 112c, and 112d are removed using wet etching, and gaps 116a, 116b, and 116c are formed. Due to this step, the gaps 116a formed by the sacrifice layers 112a being removed are communicated via the gap 116b formed by the sacrifice layer 112c being removed. When the sacrifice layers 112a, 112c, and 112d are formed of silicon nitride, a phosphoric acid system solution may be used as a solution of the wet etching.

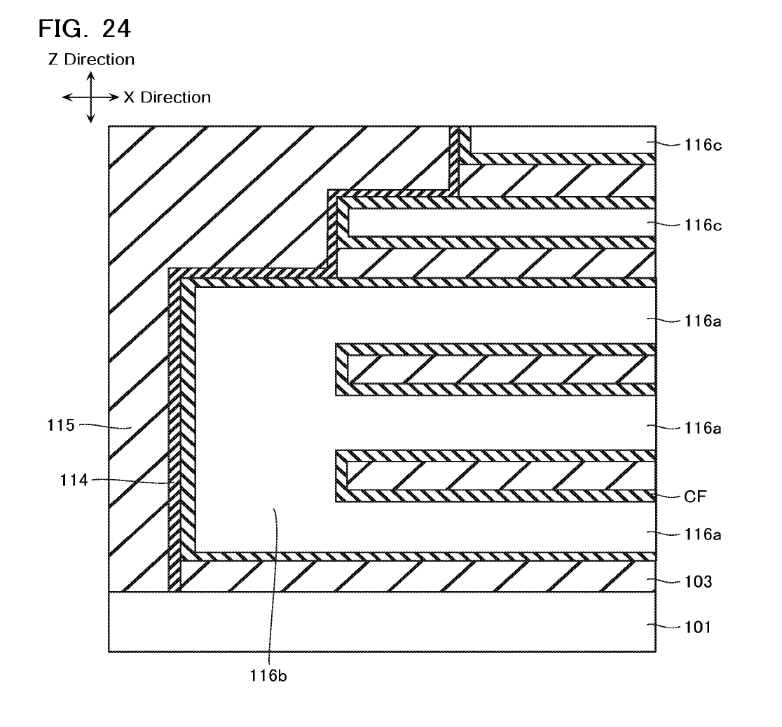

As shown in FIG. 24 which is an enlarged cross-sectional view of part of FIG. 23, the cover film CF is formed, by CVD, for example, inside the gaps 116a, 116b, and 116c caused by the wet etching. As mentioned above, this cover film CF is formed of a stacked structure of a block film, a high permittivity film, and a barrier metal, for example.

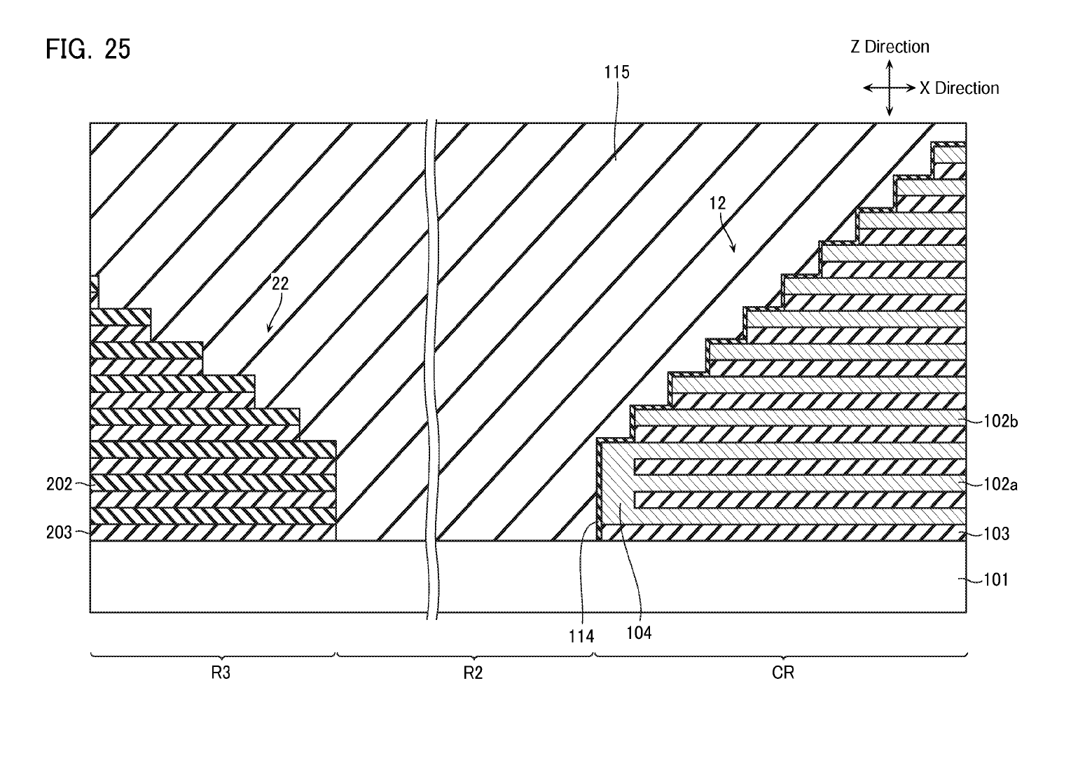

As shown in FIG. 25, the conductive film is deposited, by a CVD method, for example, inside the gaps 116a, 116b, and 116c, and the conductive layers 102a, 102b, and 104 are formed. Due to this step, the ends of the plurality of conductive layers 102a are electrically connected via the conductive layer 104 formed at those ends.

Moreover, the contact 109a connected to the conductive layer 104 and the plurality of contacts 109b connected to each layer of the conductive layers 102b, are formed, and the configuration shown in FIG. 8A is obtained.

### Second Embodiment

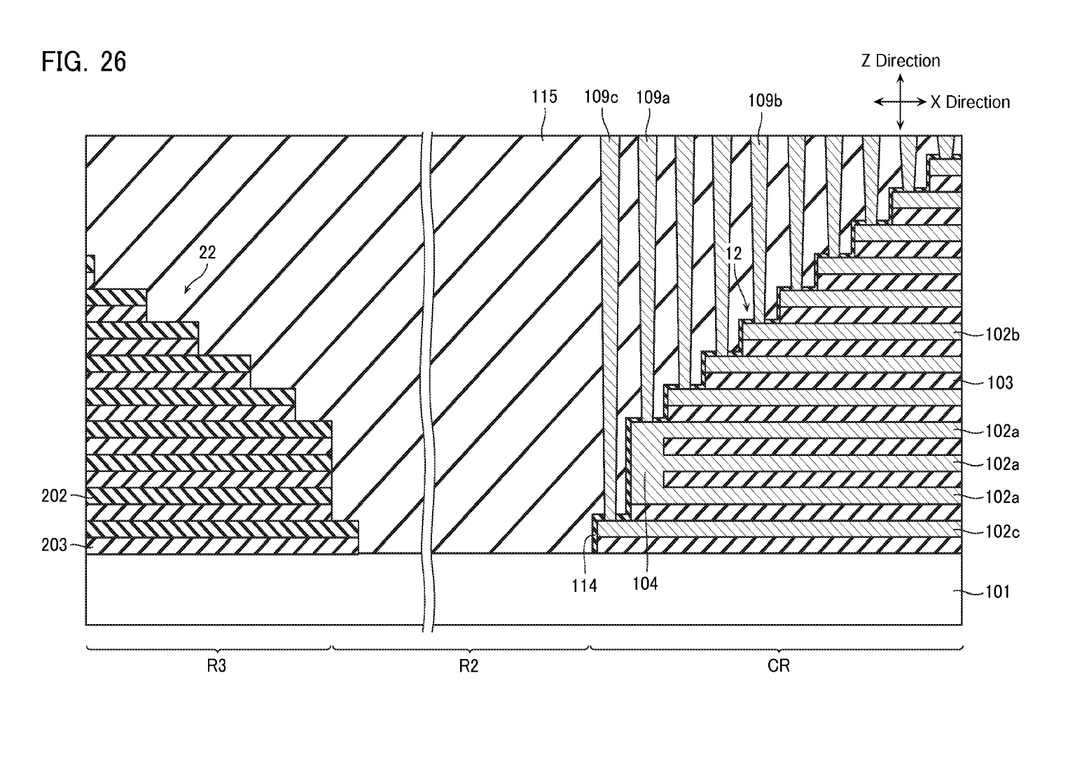

A semiconductor memory device according to a second embodiment will be described using FIGS. 26 to 36.

First, a configuration of the semiconductor memory device according to the second embodiment will be described using FIG. 26. Note that the same configurations as in the first embodiment are assigned with the same reference symbols as those assigned in the first embodiment, and descriptions thereof will be omitted.

As shown in FIG. 26, the semiconductor memory device according to the second embodiment is similar to that of the first embodiment in having the conductive layer 104 provided at the ends of some of the stacked conductive layers, that is, the conductive layers 102a. The second embodiment differs from the first embodiment in having a conductive layer 102c disposed between the conductive layers 102a and conductive layer 104 and the semiconductor substrate 101.

The conductive layer 102c is disposed downwardly of the conductive layer 102a functioning as the source side select gate line SGS and has its end in the X direction protruding more to a peripheral circuit region R2 and dummy region R3 side than does the end in the X direction of the conductive layer 104. A contact 109c is connected to the end of the conductive layer 102c. Moreover, the conductive layer 102c functions as a bottom source side select gate line SGSB.

Such a configuration also results in there being a single contact 109a as a contact for electrically connecting the plurality of conductive layers 102a and an upper wiring line. Therefore, area of the contact region CR can be reduced similarly to in the first embodiment.

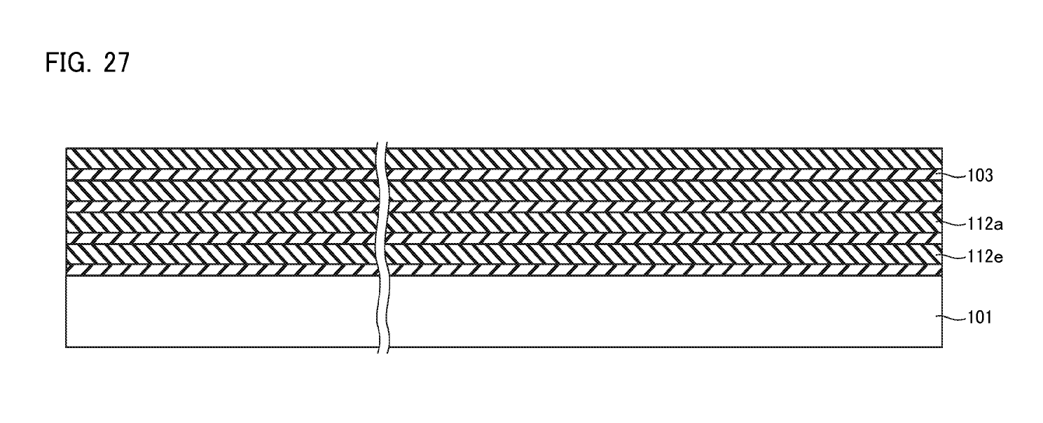

A method of manufacturing the semiconductor memory device according to the second embodiment will be described using FIGS. 27 to 36.

As shown in FIG. 27, the insulating layer 103 and a sacrifice layer 112e are stacked on the substrate 101, and a plurality of the insulating layers 103 and sacrifice layers 112a are stacked alternately on an upper surface of the sacrifice layer 112e.

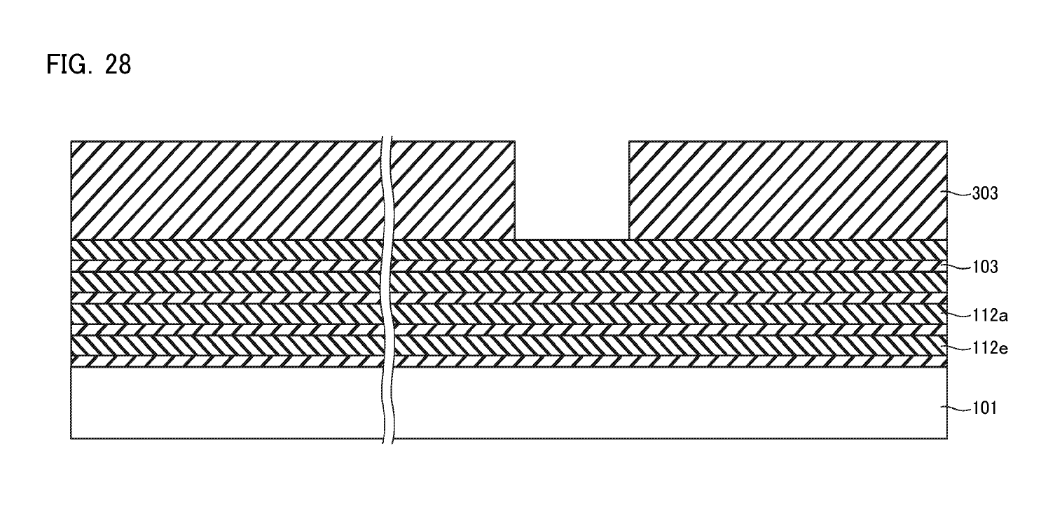

As shown in FIG. 28, a resist 303 is disposed. This step is similar to the step of FIG. 10 in the first embodiment.

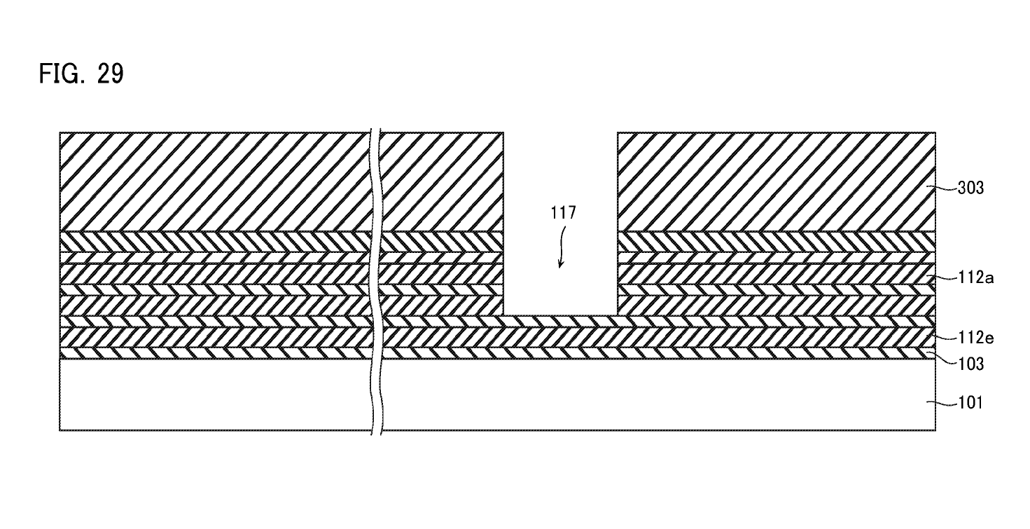

As shown in FIG. 29, parts of the insulating layers 103 and sacrifice layers 112a are removed by etching using the resist 303 as a mask. At this time, the sacrifice layer 112e is not removed. This step results in a gap 117 being formed.

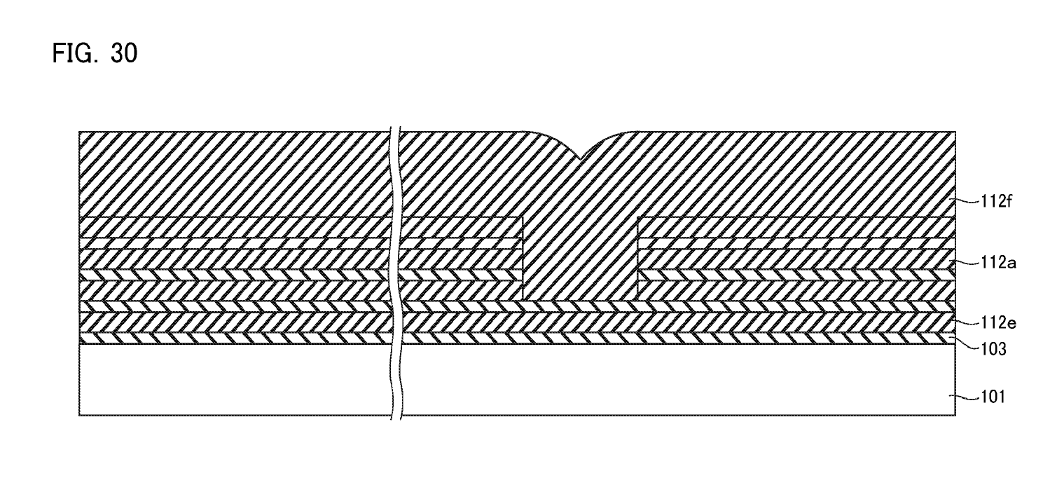

As shown in FIG. 30, the resist 303 is removed, and a sacrifice layer 112f is deposited so as to fill the gap 117. This step is similar to the step of FIG. 12 in the first embodiment.

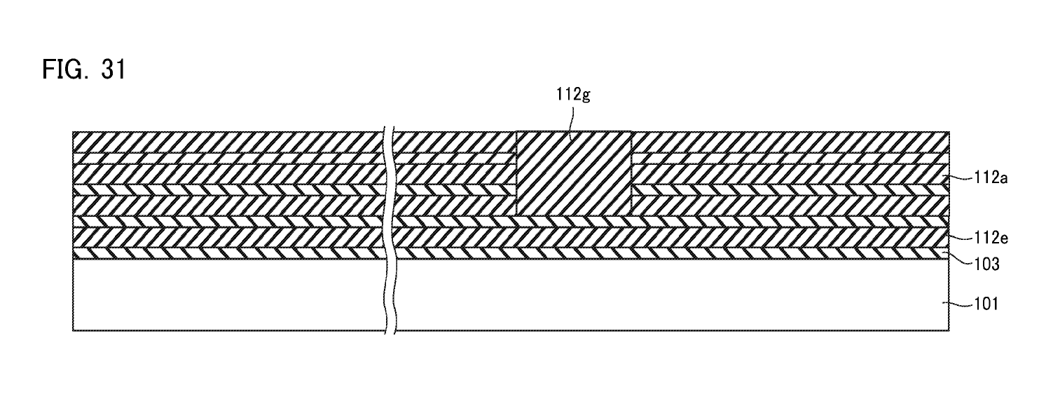

As shown in FIG. 31, the sacrifice layer 112f besides a portion implanted in the gap 117 is removed by etching or CMP. This step results in a sacrifice layer 112g being formed. This step is similar to the step of FIG. 13 in the first embodiment.

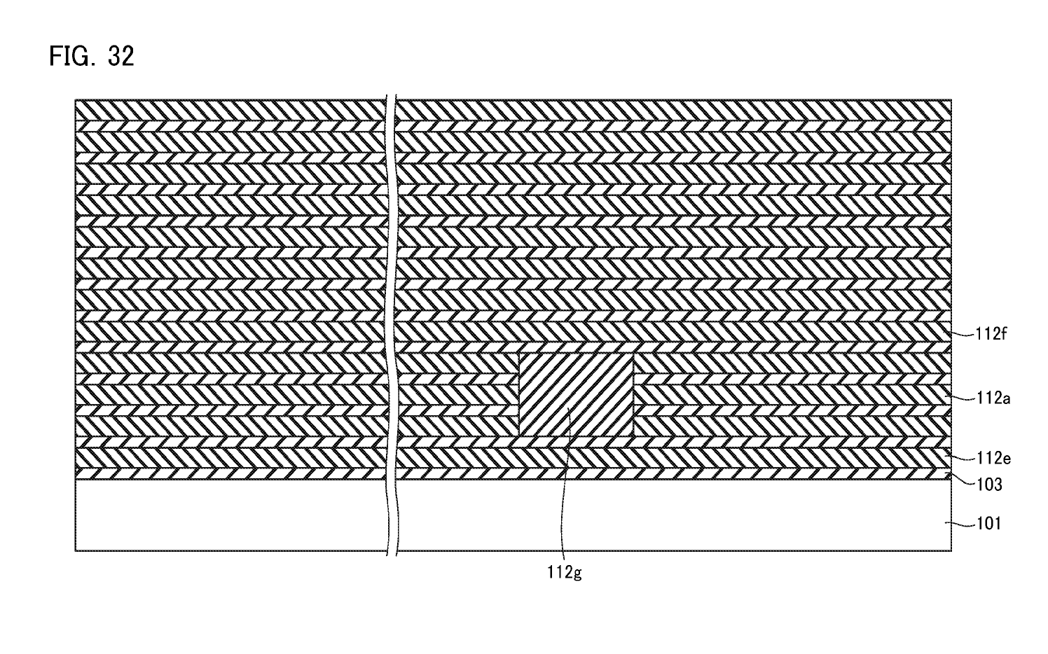

As shown in FIG. 32, a plurality of the insulating layers 103 and sacrifice layers 112d are alternately stacked. This step is similar to the step of FIG. 14 in the first embodiment.

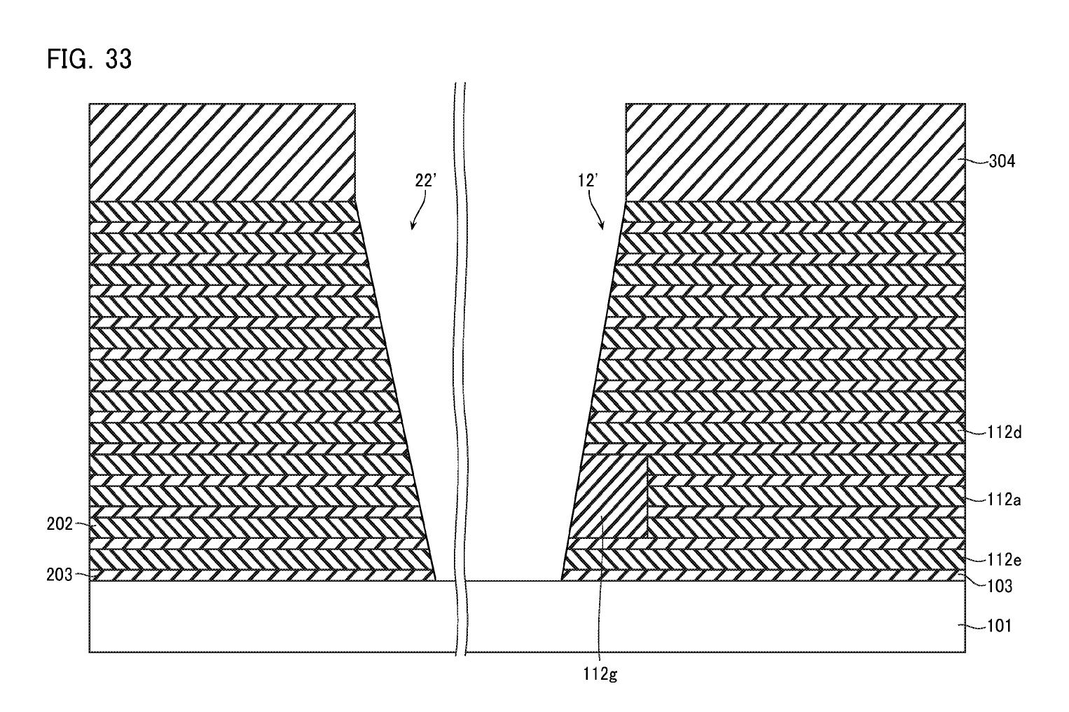

As shown in FIG. 33, the insulating layers 103 and the sacrifice layers 112a, 112d, and 112e are divided by etching using a resist 304 as a mask. In addition, part of the sacrifice layer 112g is removed.

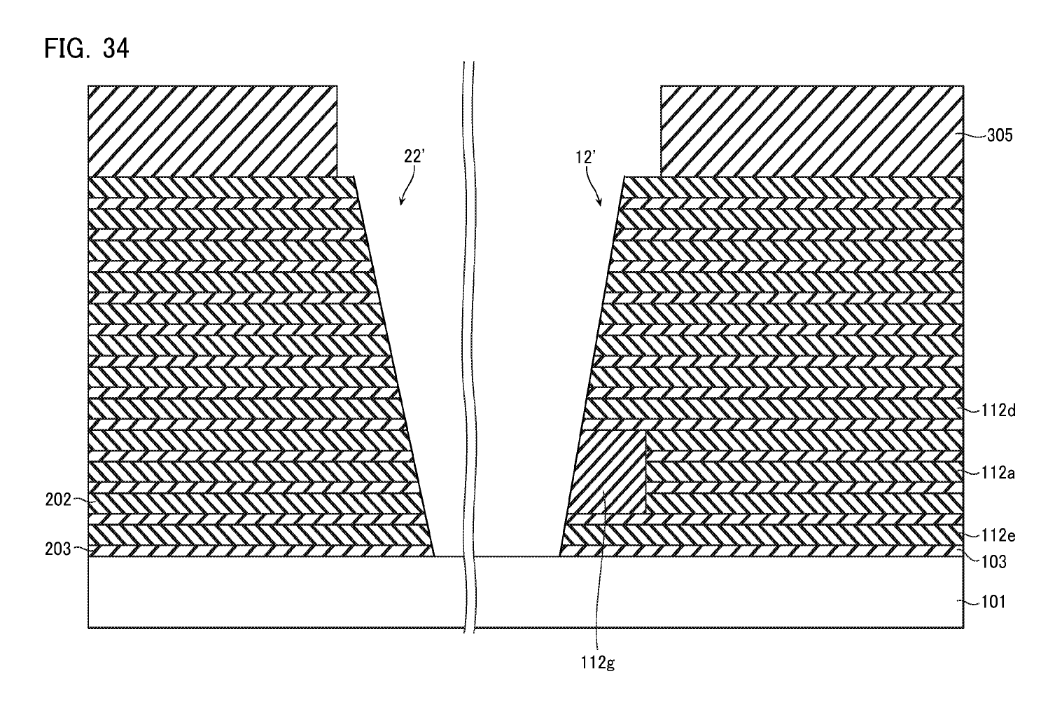

As shown in FIG. 34, the resist 304 is removed and a resist 305 is disposed.

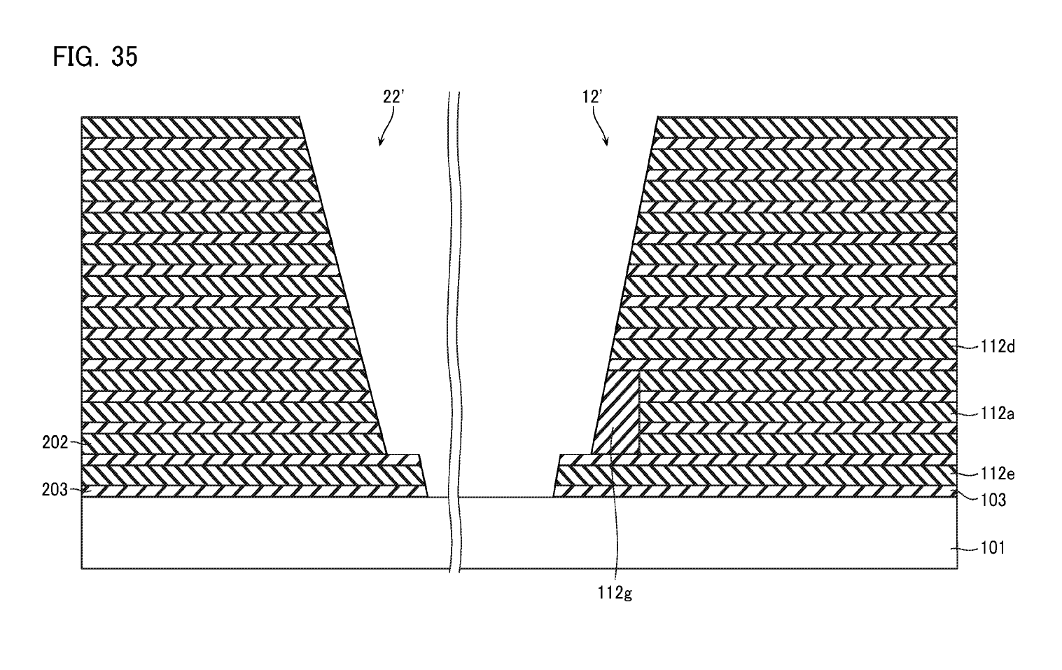

As shown in FIG. 35, parts of the insulating layers 103 and the sacrifice layers 112a and 112d are removed by etching using the resist 305 as a mask. In addition, part of the sacrifice layer 112g is removed. During this etching, conditions of the etching are adjusted such that the sacrifice layer 112e is not removed.

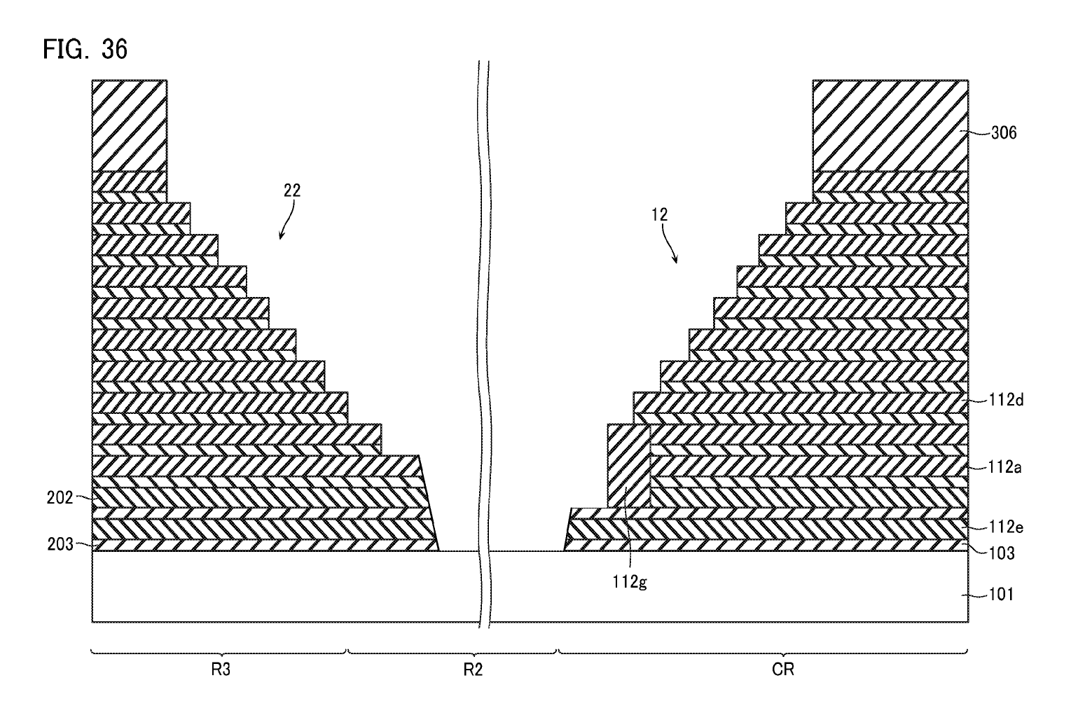

As shown in FIG. 36, etching and slimming of a resist 306 are repeated a desired number of times to form the stepped structure, similarly to in the first embodiment. During formation of this stepped structure, the sacrifice layers 112d which will later become the conductive layers 102b are all etched, whereby the stepped structure is formed, similarly to in the first embodiment. The sacrifice layers 112a which will later become the conductive layers 102a are not etched and do not undergo formation of the stepped structure. Moreover, an end in the X direction of the sacrifice layer 112e protrudes more to the peripheral circuit region R2 and dummy region R3 side than does an end in the X direction of the sacrifice layer 112c.

Hereafter, similarly to in the steps of FIGS. 22 to 25 in the first embodiment, replacement of each of the sacrifice layers by conductive layers or formation of contacts, and so on, are performed, and the configuration shown in FIG. 26 is obtained.

As described above, in the present embodiment, by twice performing the etching by which the stacked insulating layers and sacrifice layers are divided, it is made possible for the conductive layer 102c to be formed in a layer below the conductive layers 102a functioning as the select gate line SGS.

### Modified Examples

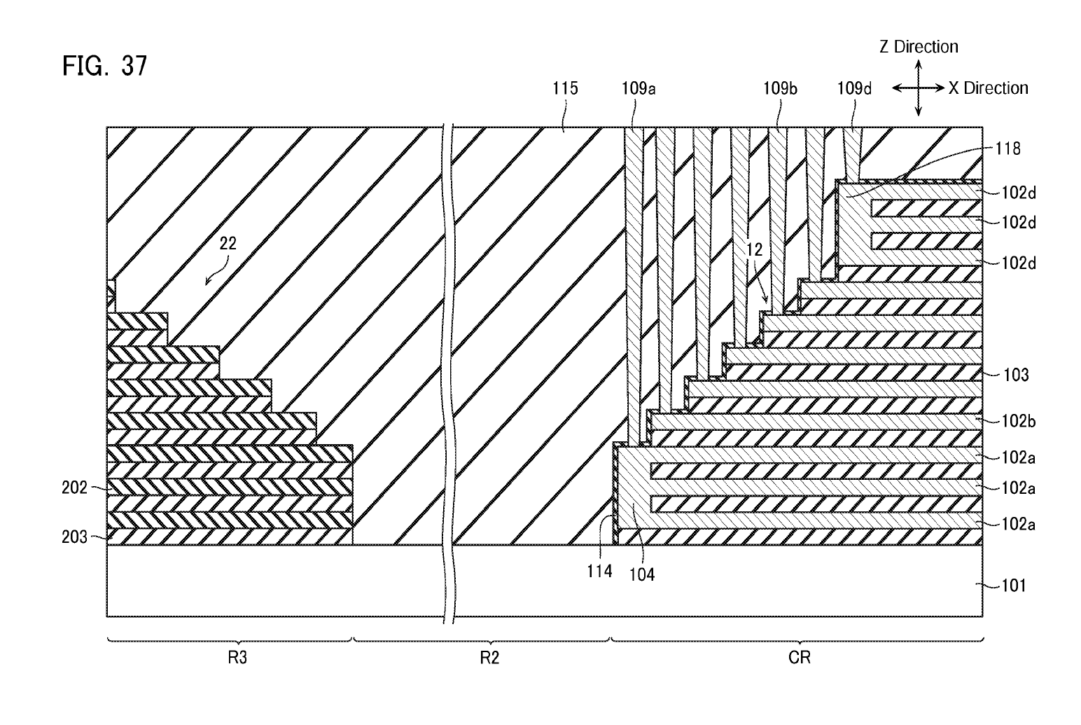

Semiconductor memory devices according to several modified examples will be described using FIGS. 37 to 39.

### First Modified Example

In the above-described embodiments, the conductive layer 104 commonly connected to the plurality of conductive layers 102a was provided only at ends of the conductive layers 102a functioning as the source side select gate line SGS.

However, as shown in FIG. 37, a conductive layer 118 commonly connected to side surfaces of a plurality of conductive layers 102d functioning as the drain side select gate line SGD, may be provided.

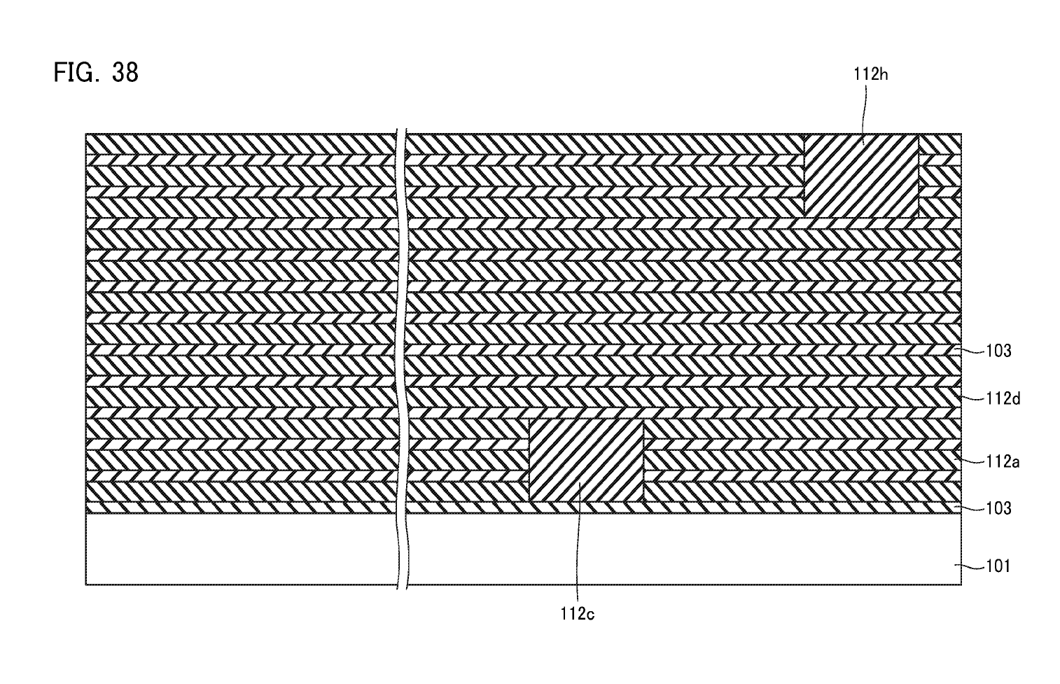

In order to form the conductive layer 118, as shown in FIG. 38, for example, the steps described by FIGS. 10 to 13 of the first embodiment are repeated a plurality of times, and a sacrifice layer 112h is formed. In addition, similar steps to those for the sacrifice layer 112c are performed on this sacrifice layer 112h, and the configuration shown in FIG. 37 is obtained.

### Second Modified Example

Moreover, in the above-described embodiments, the conductive layer 104 did not undergo etching for stepped structure formation, hence did not include the stepped structure.

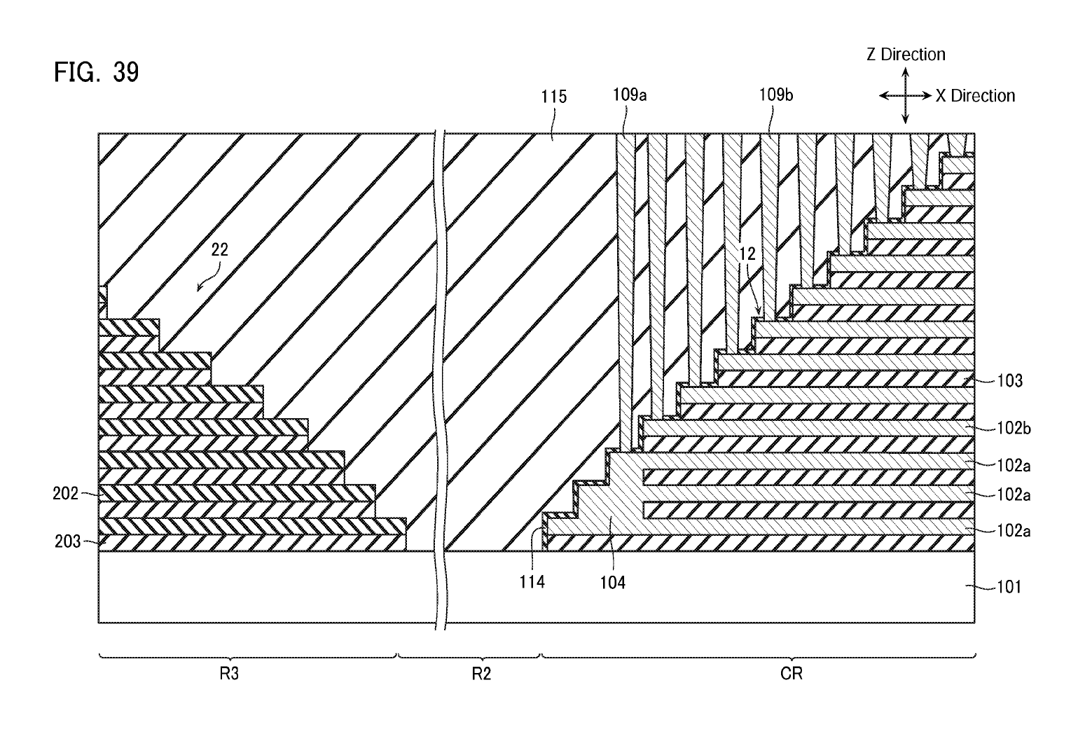

However, as shown in FIG. 39, it is also possible for the conductive layer 104 to be formed in a stepped structure shape. In order to form the conductive layer 104 in a stepped shape, it is only required that, for example, in the steps of stepped structure formation described using FIGS. 16 to 19 in the first embodiment, etching is not completed at the lowermost layer sacrifice layer 112d, and etching is performed to the sacrifice layer 112c to form in the stepped shape.

Similar advantages to those of the embodiments are obtained also by either of the above-described modified examples. Moreover, the above-described modified examples are examples, and a shape or number, and arrangement position of the conductive layer commonly connecting the plurality of conductive layers, may be appropriately changed. For example, described above was a conductive layer commonly connected to a plurality of conductive layers functioning as a select gate line, but conductive layers functioning as a dummy word line may be commonly connected. Moreover, it is also possible for the several modified examples, or for each of the embodiments and the modified examples, to be combined.

### [Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory cell array including a plurality of memory cells arranged in a stacking direction on a semiconductor substrate, and a plurality of first conductive layers arranged in the stacking direction on the semiconductor substrate and connected to the memory cells;
a cover layer that covers at least some of side surfaces of each of the plurality of first conductive layers; and
a second conductive layer commonly connected to ends of some of the plurality of first conductive layers,
wherein the commonly connected ends of some of the plurality of first conductive layers and the second conductive layer are connected without being interposed by the cover layer.

2. The semiconductor memory device according to claim 1, further comprising
a wiring line portion including the plurality of first conductive layers,
wherein the wiring line portion comprises a first stepped portion whose height decreases with increasing distance from the memory cell array.

3. The semiconductor memory device according to claim 1, wherein
the plurality of first conductive layers to which the second conductive layer is commonly connected include a lowermost layer of the plurality of first conductive layers.

4. The semiconductor memory device according to claim 1, wherein
the plurality of first conductive layers to which the second conductive layer is commonly connected include an uppermost layer of the plurality of first conductive layers.

5. The semiconductor memory device according to claim 1, further comprising
a third conductive layer disposed between the second conductive layer and the semiconductor substrate.

6. The semiconductor memory device according to claim 1, wherein
some of the plurality of first conductive layers function as a drain side select gate line,
some of the plurality of first conductive layers function as a source side select gate line, and
the second conductive layer is provided to each of the drain side select gate line and the source side select gate line.

7. The semiconductor memory device according to claim 1, wherein
the second conductive layer has a stepped structure whose height decreases with increasing distance from the memory cell array.

8. The semiconductor memory device according to claim 2, further comprising
a second stepped portion that has a structure in which a plurality of first layers and second layers are stacked alternately in the stacking direction on the semiconductor substrate, is disposed facing the first stepped portion, and has a height that increases with increasing distance from the memory cell array,
wherein a portion facing the second conductive layer of the second stepped portion has a length in a direction of increasing distance from the memory cell array which is substantially identical.

9. The semiconductor memory device according to claim 1, further comprising
a contact connected to the second conductive layer,
wherein the plurality of first conductive layers commonly connected to the second conductive layer are electrically connected to the contact via the second conductive layer.

10. A method of manufacturing a semiconductor memory device, the semiconductor memory device including: a memory cell array that includes a plurality of memory cells arranged in a stacking direction on a semiconductor substrate, and a plurality of conductive layers arranged in the stacking direction on the semiconductor substrate and connected to the memory cells; and a wiring line portion that includes the plurality of conductive layers, the method comprising:
alternately stacking a plurality of inter-layer insulating layers and first sacrifice layers on the semiconductor substrate;
forming a first gap that penetrates at least some of the plurality of inter-layer insulating layers and at least two layers of the first sacrifice layers;
depositing a second sacrifice layer inside the first gap;
alternately stacking a plurality of the inter-layer insulating layers and the first sacrifice layers on the second sacrifice layer;
dividing the plurality of inter-layer insulating layers and the plurality of first sacrifice layers by a first etching to form a first portion and a second portion, the first portion including at its end the second sacrifice layer; and
replacing the plurality of first sacrifice layers and the second sacrifice layer included in the first portion to form the plurality of conductive layers.

11. The method of manufacturing a semiconductor memory device according to claim 10, comprising:
when replacing the plurality of first sacrifice layers and the second sacrifice layer included in the first portion to form the plurality of conductive layers, removing the first sacrifice layer to form a second gap and removing the second sacrifice layer to form a third gap; and
depositing a cover layer at a boundary of the second gap and the third gap and the plurality of inter-layer insulating layers.

12. The method of manufacturing a semiconductor memory device according to claim 10, comprising
performing a plurality of times of etchings on the plurality of first sacrifice layers included in the first portion to form a first stepped portion whose height decreases with increasing distance from the memory cell array.

13. The method of manufacturing a semiconductor memory device according to claim 10, comprising
performing a plurality of times of etchings on the plurality of first sacrifice layers and the second sacrifice layer included in the first portion to form a second stepped portion whose height decreases with increasing distance from the memory cell array.

14. The method of manufacturing a semiconductor memory device according to claim 12, comprising
when performing the etching, aligning a length in a direction of increasing distance from the memory cell array of the second sacrifice layer.

15. The method of manufacturing a semiconductor memory device according to claim 10, comprising:
the first gap being formed such that at least one layer of the first sacrifice layers is left below the second sacrifice layer; and
after the first etching, performing a second etching that causes recession of ends of layers located in a higher layer than the first sacrifice layer below the second sacrifice layer.

16. The method of manufacturing a semiconductor memory device according to claim 10, comprising:
causing some of the plurality of conductive layers to function as a drain side select gate line;
causing some of the plurality of conductive layers to function as a source side select gate line; and
providing the second conductive layer to each of the drain side select gate line and the source side select gate line.

17. The method of manufacturing a semiconductor memory device according to claim 10, comprising
performing a plurality of times of etchings on the second portion, and forming a third stepped portion that faces the wiring line portion and has a height that increases with increasing distance from the memory cell array.

18. The method of manufacturing a semiconductor memory device according to claim 17, comprising
aligning a length in a direction of increasing closeness to the memory cell array, of a portion facing the second sacrifice layer, of the third stepped portion.
